(19) United States
(12) Patent Application Publication
(10) Pub. No.: US 2026/0265898 A1
(43) Pub. Date: Sep. 10, 2026

(54) DEPOSITION MASK, METHOD OF MANUFACTURING THE SAME, AND ELECTRONIC DEVICE MANUFACTURED BY USING THE SAME

(71) Applicant: Samsung Display Co., Ltd., Yongin-si (KR)

(72) Inventors: Na Rae PARK, Yongin-si (KR); Hee Yeon YOO, Yongin-si (KR); Deok Chan YOON, Yongin-si (KR)

(21) Appl. No.: 19/352,332

(22) Filed: Oct. 7, 2025

(30) Foreign Application Priority Data
Mar. 7, 2025 (KR) 10-2025-0029812

(51) Int. Cl. C23C 14/04; H10K 59/12; H10K 59/121; H10K 71/16

(52) U.S. Cl. CPC C23C 14/042; H10K 59/1201; H10K 59/121; H10K 71/166

(57) ABSTRACT

A deposition mask, a method of manufacturing the deposition mask, and an electronic device manufactured by utilizing the deposition mask are disclosed. The deposition mask may include a mask substrate having a cell opening, and a membrane on the mask substrate and having pixel openings to communicate with the cell opening. The membrane may include a first membrane on the mask substrate and a second membrane on the first membrane. The pixel openings may include first pixel openings extending through the first membrane and second pixel openings extending through the second membrane, and a distance between the first pixel openings may be smaller than a distance between the second pixel openings.

### CROSS-REFERENCE TO RELATED APPLICATION

The present application claims priority to and the benefit of Korean Patent Application No. 10-2025-0029812, filed on Mar. 7, 2025, in the Korean Intellectual Property Office, the entire disclosure of which is incorporated herein by reference.

### BACKGROUND

### 1. Field

One or more embodiments of the present disclosure relate to a deposition mask, a method of manufacturing the deposition mask, and an electronic device manufactured by utilizing the deposition mask.

### 2. Description of the Related Art

Wearable devices that focus images at a distance close to user's eyes have been developed in the form of glasses and/or helmets. The wearable devices may provide users with augmented reality (AR) or virtual reality (VR) visual experiences. For example, such wearable devices may include (or be) head mounted displays (HMDs) device or AR glasses.

In wearable devices, such as HMDs and/or AR glasses, a display resolution of about 3000 pixels per inch (PPI) or higher is often desired to enable prolonged use without causing dizziness or visual discomfort. To achieve such high resolution, organic light emitting diode on silicon (OLEDoS) technology has emerged as a promising solution for high-resolution, small-form-factor organic light-emitting display devices. OLEDoS refers to a technology in which organic light emitting diodes (OLEDs) are formed on a semiconductor substrate that includes complementary metal oxide semiconductor (CMOS) elements.

To manufacture a display panel with a high resolution of about 3000 PPI or higher, a high-resolution deposition mask is desired or required. For example, the deposition mask may be manufactured or fabricated by forming a membrane with a plurality of pixel openings on a mask substrate, and then partially removing the mask substrate to form cell openings that expose the pixel openings. The pixel openings may be formed by forming the membrane on the mask substrate and then performing an anisotropic etching process, such as a reactive ion etching (RIE) process.

### SUMMARY

A deposition mask may be utilized as a shadow mask in a deposition process to form light emitting layers on a backplane substrate. In the deposition process, the backplane substrate may be positioned on the deposition mask, and a deposition source to provide a vapor deposition material may be arranged under the deposition mask. The vapor deposition material may be deposited on the backplane substrate through the pixel openings, thereby forming the light emitting layers on the backplane substrate. During the manufacturing process of the deposition mask, warpage or deformation may occur due to residual stress of the membrane, a difference in thermal expansion coefficient between the mask substrate and the membrane, and/or the like. In this case, a distance between the backplane substrate and the deposition mask may become non-uniform, and, as a result, pixel position accuracy (PPA), size uniformity, and/or the like of the light emitting layers may be degraded.

One or more aspects of embodiments of the present disclosure are directed toward an improved or enhanced deposition mask capable of reducing warpage, a method of manufacturing the deposition mask, and an electronic device manufactured by utilizing the deposition mask.

Additional aspects of embodiments will be set forth in part in the description which follows and, in part, will be apparent from the description or may be learned by practice of the presented embodiments of the disclosure.

However, embodiments of the present disclosure are not limited to those set forth herein. The above and other aspects and features of certain embodiments of the present disclosure will become more apparent to one of ordinary skill in the art to which the present disclosure pertains by referencing the detailed description of the present disclosure given.

In accordance with one or more embodiments of the present disclosure, a deposition mask may include a mask substrate having a cell opening, and a membrane arranged on the mask substrate and having pixel openings to communicate with the cell opening. The membrane may include a first membrane arranged on the mask substrate and a second membrane arranged on the first membrane. The pixel openings may include first pixel openings extending through the first membrane and second pixel openings extending through the second membrane, and a distance between the first pixel openings may be smaller than a distance between the second pixel openings.

In accordance with one or more embodiments of the present disclosure, the distance between the first pixel openings may range from about 0.2 times to about 0.8 times the distance between the second pixel openings.

In accordance with one or more embodiments of the present disclosure, one selected from the first membrane and the second membrane may have residual tensile stress, and another one selected from the first membrane and the second membrane may have residual compressive stress.

In accordance with one or more embodiments of the present disclosure, the first membrane may include silicon oxide and/or metal having residual compressive stress, and the second membrane may include silicon nitride having residual tensile stress.

In accordance with one or more embodiments of the present disclosure, the membrane may be arranged on a front surface of the mask substrate. If (e.g., when) the first membrane includes the silicon oxide, an intermediate inorganic film having residual compressive stress may be arranged on a rear surface of the mask substrate, and a rear inorganic film having residual tensile stress may be arranged on the intermediate inorganic film.

In accordance with one or more embodiments of the present disclosure, if (e.g., when) the first membrane includes the metal, a rear inorganic film having residual tensile stress may be arranged on a rear surface of the mask substrate. In such case, the rear inorganic film may include silicon nitride and have a thickness less than a thickness of the second membrane.

In accordance with one or more embodiments of the present disclosure, the first membrane may include silicon nitride having residual tensile stress, and the second membrane may include metal having residual compressive stress. In such case, the membrane may be arranged on a front surface of the mask substrate, and a rear inorganic film having residual compressive stress may be arranged on a rear surface of the mask substrate.

In accordance with one or more embodiments of the present disclosure, the first membrane may be a composite film in which a plurality of silicon oxide films and at least one silicon nitride film are alternately stacked, and the second membrane may include silicon nitride having residual tensile stress.

In accordance with one or more embodiments of the present disclosure, a method of manufacturing a deposition mask may include forming a first membrane on a mask substrate, forming a second membrane on the first membrane, forming second pixel openings extending through the second membrane, forming a cell opening exposing the first membrane through the mask substrate, and forming first pixel openings connecting the second pixel openings and the cell opening through the first membrane. A distance between the first pixel openings may be smaller than a distance between the second pixel openings.

In accordance with one or more embodiments of the present disclosure, the first membrane may include silicon oxide and/or metal having residual compressive stress, and the second membrane may include silicon nitride having residual tensile stress.

In accordance with one or more embodiments of the present disclosure, the first membrane may include silicon nitride having residual tensile stress, and the second membrane may include metal having residual compressive stress.

In accordance with one or more embodiments of the present disclosure, the first membrane may be a composite film in which a plurality of silicon oxide films and at least one silicon nitride film are alternately stacked, and the second membrane may include silicon nitride having residual tensile stress.

In accordance with one or more embodiments of the present disclosure, the forming of the first pixel openings may include forming a photoresist pattern that exposes portions where the first pixel openings are to be formed on the first membrane exposed through the cell opening, and performing an etching process utilizing the photoresist pattern as an etching mask to form the first pixel openings.

In accordance with one or more embodiments of the present disclosure, the forming of the photoresist pattern may include forming a photoresist film on the first membrane exposed through the cell opening by performing a conformal coating process, and forming the photoresist pattern by performing an exposure process and a development process.

In accordance with one or more embodiments of the present disclosure, the forming of the first pixel openings may include forming an etch stop film on the first membrane exposed through the cell opening, and performing an etching process utilizing the second membrane as an etching mask to form the first pixel openings.

In accordance with one or more embodiments of the present disclosure, the etch stop film may be a photoresist film formed by a conformal coating process or an amorphous (e.g., non-crystalline) silicon film formed by a chemical vapor deposition process.

In accordance with one or more embodiments of the present disclosure, an electronic device may include a display panel. The display panel may include a backplane substrate and a plurality of light emitting layers formed on the backplane substrate by utilizing a deposition mask. The deposition mask may include a mask substrate having a cell opening, and a membrane arranged on the mask substrate and having pixel openings to communicate with the cell opening. The membrane may include a first membrane arranged on the mask substrate and a second membrane arranged on the first membrane. The pixel openings may include first pixel openings extending through the first membrane and second pixel openings extending through the second membrane. A distance between the first pixel openings may be smaller than a distance between the second pixel openings, and the plurality of light emitting layers may be formed by a deposition process that provides a vapor deposition material through the cell opening and the pixel openings.

In accordance with one or more embodiments of the present disclosure, the electronic device may further include at least one selected from among a processor, a memory, and a power module.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

According to one or more embodiments of the present disclosure, a first membrane may have a residual stress different from a residual stress of a second membrane, and cell warpage (e.g., a degree or occurrence of cell warpage) of the deposition mask may be reduced by the first membrane and the second membrane. Also, global warpage (e.g., a degree or occurrence of global warpage) of the deposition mask may be reduced by an intermediate inorganic film and a rear inorganic film. Accordingly, the pixel position accuracy (PPA) and size uniformity of the light emitting layers formed on the backplane substrate may be significantly or substantially improved or enhanced. For example, the deposition mask according to one or more embodiments of the present disclosure incorporates a multi-layer membrane structure with differentiated residual stress characteristics, including combinations of silicon oxide, silicon nitride, and metal films. This configuration or arrangement enables precise control over warpage at both (e.g., simultaneously) the cell and global levels, thereby maintaining a uniform (e.g., substantially uniform) gap between the deposition mask and the backplane substrate during vapor deposition. As a result, the pixel position accuracy (PPA) and size uniformity of the light-emitting layers are significantly or substantially improved or enhanced, supporting the fabrication of high-resolution display panels suitable for electronic devices, such as AR/VR head-mounted displays.

### BRIEF DESCRIPTION OF THE DRAWINGS

The above and other aspects and features of certain embodiments of the present disclosure will become more apparent from the following description taken in conjunction with the accompanying drawings, in which:

FIG. 1 is a block diagram of an electronic device according to one or more embodiments of the present disclosure;

FIG. 2 is schematic diagrams of electronic devices according to one or more embodiments of the present disclosure;

FIG. 3 is an exploded perspective view illustrating a display device according to one or more embodiments of the present disclosure;

FIG. 4 is a block diagram illustrating the display device as illustrated in FIG. 3;

FIG. 5 is an equivalent circuit diagram illustrating an example of a first sub-pixel as illustrated in FIG. 4;

FIG. 6 is a schematic plan view illustrating an example of a display panel as illustrated in FIG. 3;

FIG. 7 is a schematic enlarged plan view illustrating an example of a display area as illustrated in FIG. 6;

FIG. 8 is a schematic enlarged plan view illustrating another example of the display area as illustrated in FIG. 6;

FIG. 9 is a schematic cross-sectional view illustrating an example of the display panel taken along the line I1-I1′ shown in FIG. 7;

FIG. 10 is a schematic cross-sectional view illustrating another example of the display panel taken along the line I1-I1′ shown in FIG. 7;

FIG. 11 is a schematic cross-sectional view illustrating another example of the display panel taken along the line I1-I1′ shown in FIG. 7;

FIG. 12 is a schematic perspective view illustrating one example of a head mounted display;

FIG. 13 is a schematic exploded perspective view illustrating the head mounted display as illustrated in FIG. 12;

FIG. 14 is a schematic perspective view illustrating another example of a head mounted display;

FIG. 15 is a schematic diagram illustrating a deposition mask and a deposition apparatus including the deposition mask according to one or more embodiments;

FIG. 16 is a schematic bottom view illustrating a backplane substrate as illustrated in FIG. 15;

FIG. 17 is a schematic plan view illustrating a deposition mask as illustrated in FIG. 15;

FIG. 18 is a schematic plan view illustrating mask cell regions as illustrated in FIG. 17;

FIG. 19 is a schematic cross-sectional view taken along the line I2-I2′ shown in FIG. 18;

FIG. 20 is a schematic enlarged cross-sectional view illustrating another example of a membrane as illustrated in FIG. 19;

FIGS. 21-27 are schematic cross-sectional views illustrating a method of manufacturing a deposition mask according to one or more embodiments of the present disclosure; and

FIGS. 28 and 29 are schematic cross-sectional views illustrating a method of manufacturing a deposition mask according to one or more embodiments of the present disclosure.

### DETAILED DESCRIPTION

The subject matter of the present disclosure will be described more fully hereinafter with reference to the accompanying drawings, in which one or more embodiments of the present disclosure are shown. The subject matter of the present disclosure may, however, be embodied in different forms and should not be construed as being limited to the embodiments set forth herein, and one or more changes and modifications can be made. Rather, these embodiments are provided so that this disclosure will be thorough and complete and will fully convey the aspects and features of the present disclosure to those skilled in the art to which the present disclosure pertains.

The utilization of “may,” if (e.g., when) describing embodiments of the present disclosure, refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

It will also be understood that if (e.g., when) an element or a layer is referred to as being “on” or “above” another element or layer, it may be directly on or directly above the other element or layer, or intervening layers may also be present therebetween. In contrast, if (e.g., when) an element or a layer is referred to as being “directly on” or “directly above” another element or layer, there may be no intervening layers present therebetween.

The same reference numbers indicate substantially the same components throughout the specification.

In the attached drawings, the thickness of layers and regions may be exaggerated to effectively or suitably illustrate the technical contents of the present disclosure.

It will be understood that, although the terms “first,” “second,” and/or the like may be used herein to describe one or more suitable elements, these elements should not be limited by these terms. These terms are only used to distinguish one element from another element. For instance, a first element discussed herein may be termed a second element without departing from the scope of the present disclosure. Similarly, the second element may also be termed the first element.

The terminology used herein is for the purpose of describing particular embodiments only and is not intended to be limiting.

As used herein, “a”, “an,” “the,” and “at least one” do not denote a limitation of quantity and are intended to include both (e.g., simultaneously) the singular and plural, unless the context clearly indicates otherwise. For example, “an element” has substantially the same meaning as “at least one element,” unless the context clearly indicates otherwise. “At least one” is not to be construed as limiting “a” or “an.”

“Or” refers to “and/or.” As used herein, the term “and/or” includes any and all combinations of one or more of the associated listed items.

It will be further understood that the terms “has,” “having,” “includes,” and/or “including,” if (e.g., when) used in this specification, specify the presence of stated features, regions, integers, steps, operations, elements, and/or components, but do not preclude the presence or addition of one or more other features, regions, integers, steps, operations, elements, components, and/or groups thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Furthermore, relative terms, such as “lower” or “bottom” and “upper” or “top,” may be used herein to describe one element's relationship to another element as illustrated in the drawings. It will be understood that relative terms are intended to encompass different orientations of the device in addition to the orientation illustrated in the drawings. For example, if (e.g., when) the device in one of the drawings is turned over, elements described as being on the “lower” side of other elements may then be oriented on “upper” sides of the other elements. The term “lower” may, therefore, encompass both (e.g., simultaneously) an orientation of “lower” and “upper,” depending on the particular orientation of the drawing. Similarly, if (e.g., when) the device in one of the drawings is turned over, elements described as “below” or “beneath” other elements may then be oriented “above” the other elements. The terms “below” or “beneath” may, therefore, encompass both (e.g., simultaneously) an orientation of above and below.

Features of each of one or more embodiments of the present disclosure may be partially or entirely combined with each other and may technically suitably interwork with each other, and respective embodiments may be implemented independently of each other or may be implemented together in association with each other.

“About” or “approximately” as used herein is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value.

Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

Unless otherwise defined, all terms (including technical and scientific terms) used herein have substantially the same meaning as generally understood by one of ordinary skill in the art to which this disclosure belongs. It will be further understood that terms, such as those defined in generally used dictionaries, should be interpreted as having a meaning that is consistent with their meaning in the context of the relevant art and the present disclosure and will not be interpreted in an idealized or overly formal sense unless expressly so defined herein.

One or more embodiments of the present disclosure are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as being limited to the particular shapes of regions as illustrated herein but are to include deviations in shapes that result, for example, from manufacturing. For example, a region illustrated or described as flat may have rough and/or nonlinear features. Moreover, sharp angles that are illustrated may be rounded. Thus, the regions illustrated in the drawings are schematic in nature and their shapes are not intended to illustrate the precise shape of a region and are not intended to limit the scope of the present claims.

Hereinafter, one or more embodiments of the present disclosure will be described in more detail with reference to the accompanying drawings.

The display device according to one or more embodiments of the present disclosure may be applied to one or more suitable electronic devices. The electronic device according to one or more embodiments of the present disclosure may include the display device as described herein and may further include modules or devices having additional functions in addition to the display device.

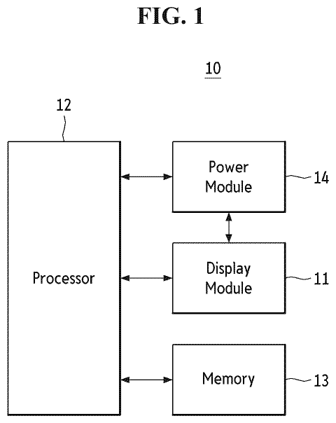

FIG. 1 is a block diagram of an electronic device according to one or more embodiments of the present disclosure.

Referring to FIG. 1, the electronic device 10 according to one or more embodiments of the present disclosure may include a display module 11, a processor 12, a memory 13, and a power module 14.

The processor 12 may include at least one selected from among a central processing unit (CPU), an application processor (AP), a graphic processing unit (GPU), a communication processor (CP), an image signal processor (ISP), and a controller.

The memory 13 may be to store data information necessary or desirable for the operation of the processor 12 or the display module 11. If (e.g., when) the processor 12 executes an application stored in the memory 13, an image data signal and/or an input control signal may be transmitted to the display module 11, and the display module 11 may be to process the received signal and output image information through a display screen.

The power module 14 may include a power supply module, such as a power adapter or a battery, and a power conversion module that converts the power supplied by the power supply module to generate power necessary or desirable for the operation of the electronic device 10.

At least one selected from among the components of the electronic device 10 according to the one or more embodiments of the present disclosure may be included in the display device 20 according to one or more embodiments of the present disclosure. In one or more embodiments, one or more modules of the individual modules functionally included in one module may be included in the display device 20, and other modules may be provided separately from the display device 10. For example, the display device 20 may include the display module 11, and the processor 12, the memory 13, and the power module 14 may be provided in the form of other devices within the electronic device 10 other than the display device 20.

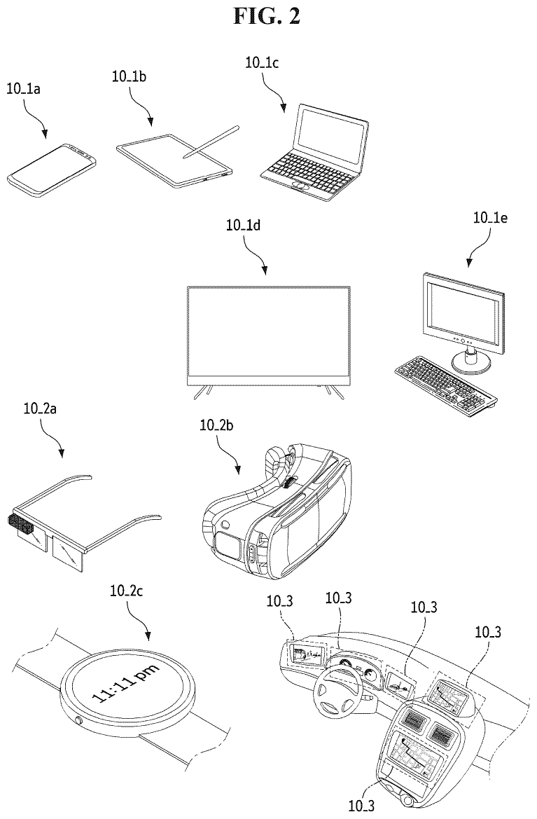

FIG. 2 is a schematic diagram of an electronic device according to one or more embodiments of the present disclosure.

Referring to FIG. 2, one or more suitable electronic devices to which display devices 20 according to one or more embodiments of the present disclosure are applied may include not only image display electronic devices, such as a smart phone 10_1a, a tablet personal computer (PC) 10_1b, a laptop 10_1c, a TV 10_1d, and a desk monitor 10_1e, but also wearable electronic devices including display modules, such as smart glasses 10_2a, a head mounted display 10_2b, and a smart watch 10_2c, and vehicle electronic devices 10_3 including display modules, such as a Center Information Display (CID) and a room mirror display arranged on a dashboard, center fascia, and dashboard of an automobile.

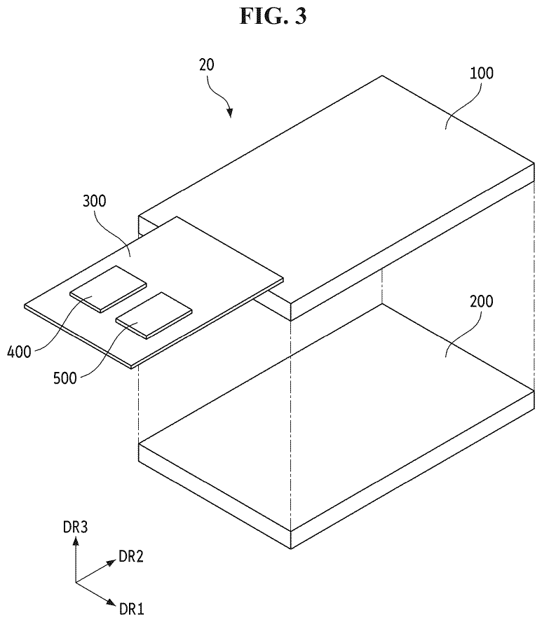

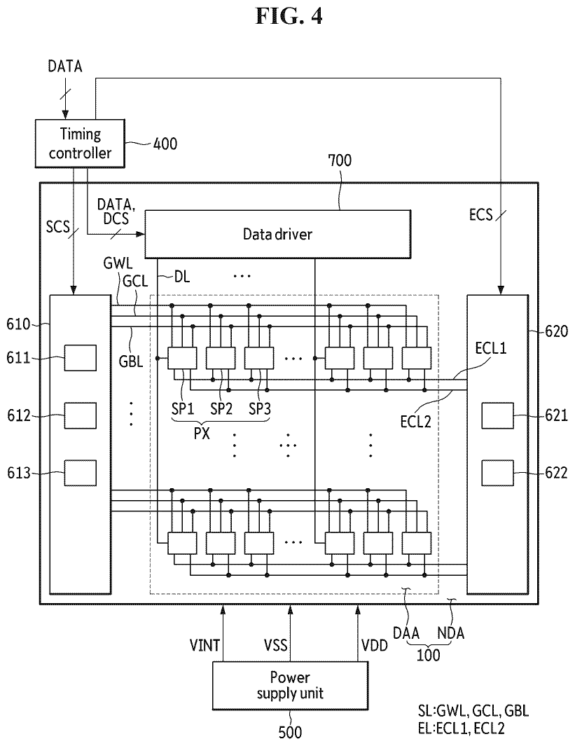

FIG. 3 is an exploded perspective view illustrating a display device according to one or more embodiments of the present disclosure. FIG. 4 is a block diagram illustrating the display device as illustrated in FIG. 3.

Referring to FIGS. 3 and 4, a display device 20 according to one or more embodiments may be a device to display a moving image or a still image. A display device 20 according to one or more embodiments may be utilized as the electronic device 10 or the display module 11 of the electronic device 10. For example, the display device 20 according to one or more embodiments may be applied to portable electronic devices 10, such as a mobile phone, a smartphone, a tablet personal computer, a mobile communication terminal, an electronic organizer, an electronic book, a portable multimedia player (PMP), a navigation system, an ultra mobile PC (UMPC), and/or the like. The display device 20 according to one or more embodiments may be applied as a display module 11 of electronic devices 10, such as a television, a laptop, a monitor, a billboard, or an Internet-of-Things (IoT) terminal, and/or the like. The display device 20 according to one or more embodiments may be applied to electronic devices 10, such as a smart watch, a watch phone, a head mounted display (HMD) to implement virtual reality and augmented reality, and/or the like.

The display device 20 according to one or more embodiments may include a display panel 100, a heat dissipation layer 200, a circuit board 300, a timing control circuit 400, and a power supply circuit 500.

The display panel 100 may have a planar shape (e.g., a substantially planar shape) similar to a quadrilateral shape (e.g., a substantially quadrilateral shape). For example, the display panel 100 may have a planar shape (e.g., a substantially planar shape) similar to a quadrilateral shape (e.g., a substantially quadrilateral shape), having a short side of a first direction DR1 and a long side of a second direction DR2 crossing (e.g., intersecting) the first direction DR1. In the display panel 100, a corner where a short side in the first direction DR1 and a long side in the second direction DR2 meet may be right-angled or rounded with a set or predetermined curvature. The planar shape of the display panel 100 is not limited to a quadrilateral shape (e.g., a substantially quadrilateral shape) and may be a shape similar to another polygonal shape (e.g., a substantially polygonal shape), a circular shape (e.g., a substantially circular shape), or an elliptical shape (e.g., a substantially elliptical shape). The planar shape of the display device 20 may conform to the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as illustrated in FIG. 4.

The plurality of pixels PX may be arranged in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines ECL1 and a plurality of second emission control lines ECL2.

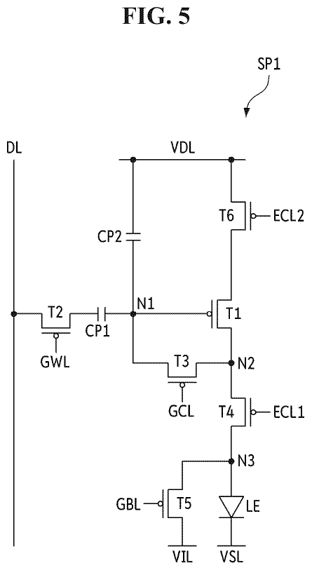

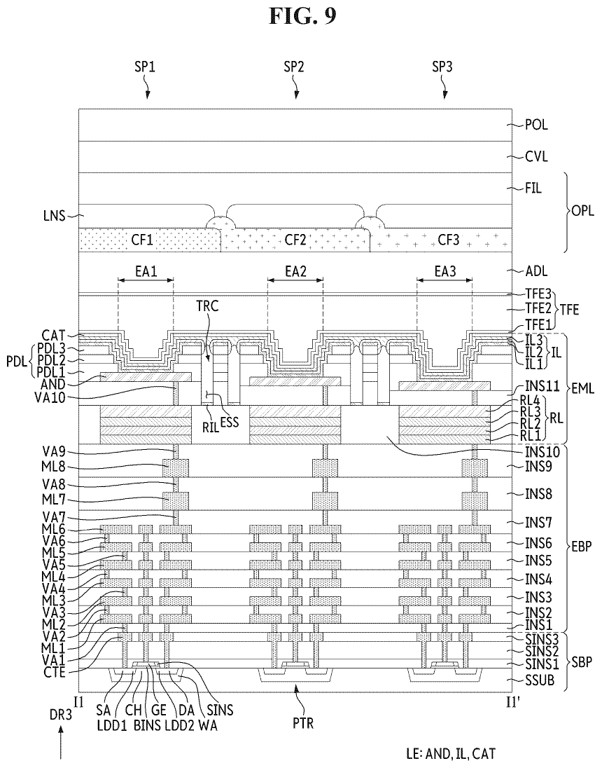

The plurality of pixels PX may include a plurality of sub-pixels SP1, SP2, and SP3. The plurality of sub-pixels SP1, SP2, and SP3 may include a plurality of pixel transistors as illustrated in FIG. 5, and the plurality of pixel transistors may be formed by a semiconductor process and arranged on a semiconductor substrate SSUB (see FIG. 9). For example, the plurality of pixel transistors of the data driver 700 may be formed or composed of complementary metal oxide semiconductor (CMOS), but embodiments of the present disclosure are not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may be to receive a data voltage of the data line DL in response to a write scan signal of the write scan line GWL, and emit light from the light emitting element according to the data voltage.

The scan driver 610, the emission driver 620, and the data driver 700 may be arranged in the non-display area NDA.

The scan driver 610 may include a plurality of scan transistors, and the emission driver 620 may include a plurality of light emitting transistors. The plurality of scan transistors and the plurality of light emitting transistors may be formed on the semiconductor substrate SSUB (see FIG. 9) through a semiconductor process. For example, the plurality of scan transistors and the plurality of light emitting transistors may be formed or composed of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may be to receive a scan timing control signal SCS from the timing control circuit 400. The write scan signal output unit 611 may be to generate write scan signals according to the scan timing control signal SCS of the timing control circuit 400 and output them sequentially to the write scan lines GWL. The control scan signal output unit 612 may be to generate control scan signals in response to the scan timing control signal SCS and sequentially output them to the control scan lines GCL. The bias scan signal output unit 613 may be to generate bias scan signals according to the scan timing control signal SCS and output them sequentially to the bias scan lines GBL.

The emission driver 620 may include a first emission control driver 621 and a second emission control driver 622. Each of the first emission control driver 621 and the second emission control driver 622 may be to receive an emission timing control signal ECS from the timing control circuit 400. The first emission control driver 621 may be to generate first emission control signals according to the emission timing control signal ECS and sequentially output them to the first emission control lines ECL1. The second emission control driver 622 may be to generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (see FIG. 9) through a semiconductor process. For example, the plurality of data transistors may be formed or composed of CMOS, but embodiments of the present disclosure are not limited thereto.

The data driver 700 may be to receive digital video data DATA and a data timing control signal DCS from the timing control circuit 400. The data driver 700 may be to convert the digital video data DATA into analog data voltages according to the data timing control signal DCS and output the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be arranged on one surface of the display panel 100, for example, on the rear surface thereof. The heat dissipation layer 200 may serve to dissipate heat generated from the display panel 100. The heat dissipation layer 200 may include a metal layer having high thermal conductivity, such as graphite, silver (Ag), copper (Cu), and/or aluminum (Al).

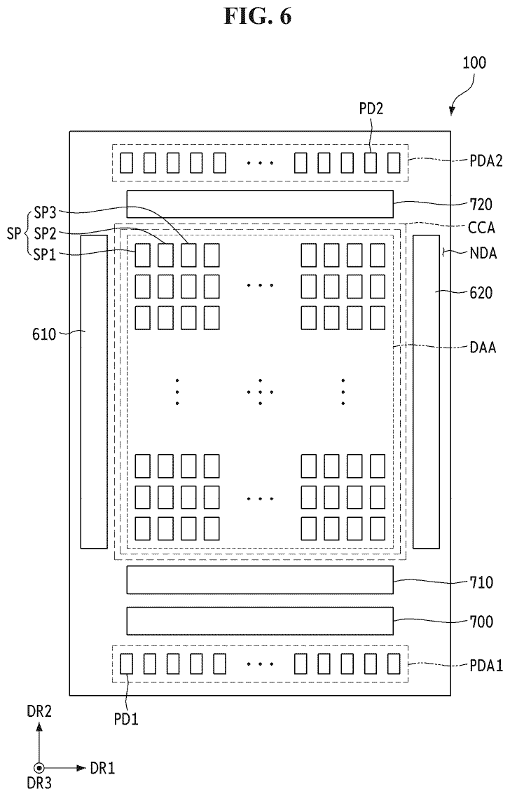

The circuit board 300 may be electrically connected to a plurality of first pads PD1 (see FIG. 6) of a first pad portion PDA1 (see FIG. 6) of the display panel 100 by utilizing a conductive (e.g., electrically conductive) adhesive member, such as an anisotropic conductive film. The circuit board 300 may be a flexible printed circuit board with a flexible material, or a flexible film. Although the circuit board 300 is illustrated in FIG. 3 as being unfolded, the circuit board 300 may be bent. In this case, one end of the circuit board 300 may be arranged on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by utilizing a conductive (e.g., electrically conductive) adhesive member. One end of the circuit board 300 may be an opposite end of the other end of the circuit board 300.

The timing control circuit 400 may be to receive digital video data and timing signals inputted from the outside. The timing control circuit 400 may be to generate the scan timing control signal SCS, the emission timing control signal ECS, and the data timing control signal DCS to control the display panel 100 in response to the timing signals. The timing control circuit 400 may be to output the scan timing control signal SCS to the scan driver 610, and output the emission timing control signal ECS to the emission driver 620. The timing control circuit 400 may be to output the digital video data and the data timing control signal DCS to the data driver 700.

The power supply circuit 500 may be to generate a plurality of panel driving voltages according to a power voltage from the outside. For example, the power supply circuit 500 may be to generate a first driving voltage VSS, a second driving voltage VDD, and a third driving voltage VINT and supply them to the display panel 100. The first driving voltage VSS, the second driving voltage VDD, and the third driving voltage VINT will be described herein in more detail in conjunction with FIG. 5.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be arranged in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 9) through a semiconductor process. For example, the plurality of timing transistors and the plurality of power transistors may be formed or composed of CMOS, but embodiments of the present disclosure are not limited thereto. Each of the timing control circuit 400 and the power supply circuit 500 may be arranged between the data driver 700 and the first pad portion PDA1 (see FIG. 6).

FIG. 5 is an equivalent circuit diagram illustrating an example of a first sub-pixel as illustrated in FIG. 4.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 may include a plurality of transistors T1 to T6, a light emitting element LE, a first capacitor CP1, and a second capacitor CP2.

The light emitting element LE may be to emit light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer arranged between the first electrode and the second electrode, but embodiments of the present disclosure are not limited thereto. For example, the light emitting element LE may be an inorganic light emitting element including a first electrode, a second electrode, and an inorganic semiconductor arranged between the first electrode and the second electrode, in which case the light emitting element LE may be a micro light emitting diode.

The first transistor T1 may be a driving transistor that controls a source-drain current (hereinafter referred to as “driving current”) flowing between the source electrode and the drain electrode thereof according to a voltage applied to the gate electrode thereof.

A second transistor T2 may be arranged between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be arranged between the first node N1 and the second node N2. The third transistor T3 may be turned on by the control scan signal of the control scan line GCL to connect the first node N1 to the second node N2. For this reason, if (e.g., when) the gate electrode and the source electrode of the first transistor T1 are connected, the first transistor T1 may operate like a diode.

The fourth transistor T4 may be connected between the second node N2 and a third node N3. The fourth transistor T4 may be turned on by the first emission control signal of the first emission control line ECL1 to connect the second node N2 to the third node N3. Accordingly, the driving current of the first transistor T1 may be supplied to the light emitting element LE. A fifth transistor T5 may be arranged between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be arranged between the source electrode of the first transistor T1 and the second driving voltage line VDL. The sixth transistor T6 may be turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 may be formed between the first node N1 and the drain electrode of the second transistor T2. The second capacitor CP2 may be formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a positive type (kind) (P-type (kind)) MOSFET, but embodiments of the present disclosure are not limited thereto. Each of the first to sixth transistors T1 to T6 may be a negative type (kind) (N-type (kind)) MOSFET. In one or more embodiments, one or more of the first to sixth transistors T1 to T6 may be P-type (kind) MOSFETs, and each of the remaining transistors may be an N-type (kind) MOSFET.

Although it is illustrated in FIG. 5 that the first sub-pixel SP1 includes six transistors T1 to T6 and two capacitors C1 and C2, it should be noted that the equivalent circuit diagram of the first sub-pixel SP1 is not limited to that illustrated in FIG. 5. For example, the number of transistors and the number of capacitors of the first sub-pixel SP1 are not limited to those illustrated in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 as described in conjunction with FIG. 5. Therefore, the description of the equivalent circuit diagram of the second sub-pixel SP2 and the equivalent circuit diagram of the third sub-pixel SP3 may not be repeated in the present disclosure.

FIG. 6 is a schematic plan view illustrating an example of a display panel as illustrated in FIG. 3.

Referring to FIG. 6, the display area DAA of the display panel 100 according to one or more embodiments may include the plurality of pixels PX arranged in a matrix form. The non-display area NDA of the display panel 100 according to one or more embodiments may include the scan driver 610, the emission driver 620, the data driver 700, a first distribution circuit 710, a second distribution circuit 720, the first pad portion PDA1, and a second pad portion PDA2.

The scan driver 610 may be arranged on the first side of the display area DAA, and the emission driver 620 may be arranged on the second side of the display area DAA. For example, the scan driver 610 may be arranged on one side of the display area DAA in the first direction DR1, and the emission driver 620 may be arranged on the other side of the display area DAA in the first direction DR1. However, embodiments of the present disclosure are not limited thereto, and the scan driver 610 and the emission driver 620 may be arranged on both (e.g., simultaneously) the first side and the second side of the display area DAA.

The first pad portion PDA1 may include the plurality of first pads PD1 connected to pads or bumps of the circuit board 300 through a conductive (e.g., electrically conductive) adhesive member. The first pad portion PDA1 may be arranged on the third side of the display area DAA. For example, the first pad portion PDA1 may be arranged on one side of the display area DAA in the second direction DR2. The first pad portion PDA1 may be arranged outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process or may be connected to a circuit board for inspection. The circuit board for inspection may be a printed circuit board made or composed of a rigid material or a flexible printed circuit board made or composed of a flexible material.

The second pad portion PDA2 may be arranged on the fourth side of the display area DAA. For example, the second pad portion PDA2 may be arranged on the other side of the display area DAA in the second direction DR2. The second pad portion PDA2 may be arranged outside the second distribution circuit 720 in the second direction DR2.

The first distribution circuit 710 may be to distribute data voltages applied through the first pad portion PDA1 to the plurality of data lines DL. For example, the first distribution circuit 710 may be to distribute the data voltages applied through one first pad PD1 of the first pad portion PDA1 to the P (P is a positive integer of 2 or more) data lines DL, and, as a result, the number of the plurality of first pads PD1 may be reduced. The first distribution circuit 710 may be arranged on the third side of the display area DAA of the display panel 100. For example, the first distribution circuit 710 may be arranged on one side of the display area DAA in the second direction DR2.

The second distribution circuit 720 may be to distribute signals applied through the second pad portion PDA2 to the scan driver 610, the emission driver 620, and the data lines DL. The second pad portion PDA2 and the second distribution circuit 720 may be configured or arranged to inspect the operation of each of the pixels PX in the display area DAA. The second distribution circuit 720 may be arranged on the fourth side of the display area DAA of the display panel 100. For example, the second distribution circuit 720 may be arranged on the other side of the display area DAA in the second direction DR2.

A cathode connection part CCA may be a region where a second electrode CAT (see FIG. 9) of a display element layer EML (see FIG. 9) is connected to the first driving voltage line VSL of the non-display area NDA. The cathode connection part CCA may be arranged outside at least one side of the display area DAA. For example, the cathode connection part CCA may be arranged outside at least on one side among the left side, the right side, the upper side, and the lower side of the display area DAA. In one or more embodiments, the cathode connection part CCA may be arranged to be around (e.g., surround) the display area DAA as illustrated in FIG. 6 in order to minimize or reduce a deviation in the first driving voltage VSS caused by voltage drop (IR drop) or voltage rise (IR rising) of the second electrode CAT in the display area DAA.

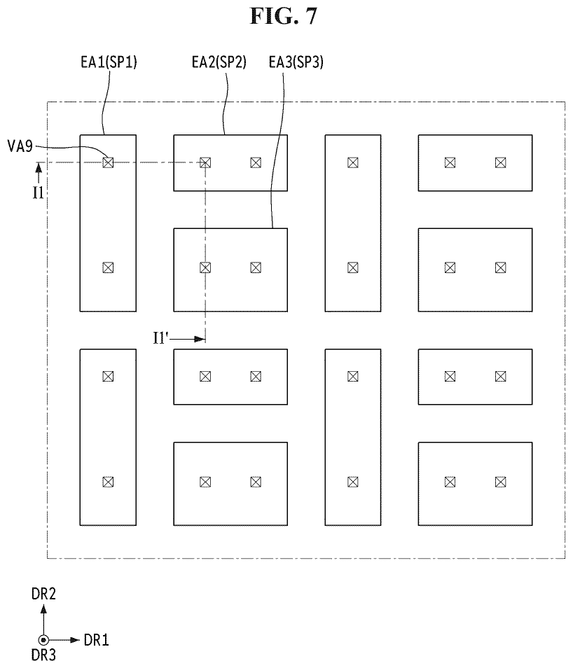

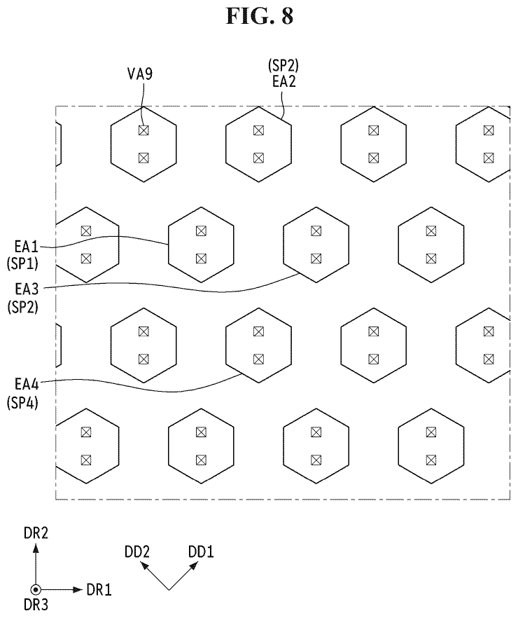

FIG. 7 is a schematic enlarged plan view illustrating an example of a display area as illustrated in FIG. 6. FIG. 8 is a schematic enlarged plan view illustrating another example of the display area as illustrated in FIG. 6.

Referring to FIGS. 7 and 8, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in plan view, a quadrilateral shape (e.g., a substantially quadrilateral shape) or a hexagonal shape (e.g., a substantially hexagonal shape) as illustrated in FIGS. 7 and 8, but embodiments of the present disclosure are not limited thereto. The first emission area EA1, the second emission area EA2, and the third emission area EA3 may have a polygonal shape (e.g., a substantially polygonal shape) other than a quadrangle (e.g., a substantially quadrilateral shape), a hexagon (e.g., a substantially hexagonal shape), a circular shape (e.g., a substantially circular shape), an elliptical shape (e.g., a substantially elliptical shape), or an atypical shape in plan view.

As illustrated in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In one or more embodiments, the second emission area EA2 and the third emission area EA3 may be adjacent to each other in the second direction DR2. The area of the first emission area EA1, the area of the second emission area EA2, and the area of the third emission area EA3 may be different.

In one or more embodiments, as illustrated in FIG. 8, the emission areas EA1, EA2, EA3, and EA4 may have a hexagonal shape (e.g., a substantially hexagonal shape) in plan view. In this case, the first emission area EA1 and the third emission area EA3 may be adjacent in the first direction DR1, and the second emission area EA2 and the fourth emission area EA4 may be adjacent in the second direction DR2. In one or more embodiments, the first emission area EA1 and the second emission area EA2 may be adjacent in a first diagonal direction DD1, and the second emission area EA2 and the third emission area EA3 may be adjacent in a second diagonal direction DD2. In one or more embodiments, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2 and may refer to a direction inclined by 45 degrees with respect to the first direction DR1 and the second direction DR2, and the second diagonal direction DD2 may be a direction normal (e.g., substantially perpendicular) to the first diagonal direction DD1.

The first sub-pixel SP1 may be to emit first light, the second sub-pixel SP2 may be to emit second light, and the third sub-pixel SP3 may be to emit third light. Herein, the first light may be light of a blue wavelength band, the second light may be light of a green wavelength band, and the third light may be light of a red wavelength band. For example, the blue wavelength band may be a wavelength band of light whose main or predominant peak wavelength is in the range of about 370 nm to about 460 nm, the green wavelength band may be a wavelength band of light whose main or predominant peak wavelength is in the range of about 480 nm to about 560 nm, and the red wavelength band may be a wavelength band of light whose main or predominant peak wavelength is in the range of about 600 nm to about 750 nm.

As illustrated in FIG. 7, each of the plurality of pixels PX may include three emission areas EA1, EA2, and EA3 or may include four emission areas EA1, EA2, EA3, and EA4 as illustrated in FIG. 8. In this case, the fourth emission area EA4 may be to emit substantially the same second light as the second emission area EA2, but embodiments of the present disclosure are not limited thereto.

The emission areas of the plurality of pixels PX may be arranged in a stripe structure in which the emission areas are arranged in the first direction DR1, a PENTILE® arrangement structure (e.g., an RGBG matrix, an RGBG structure, or an RGBG matrix structure) in which the emission areas EA1, EA2, EA3, and EA4 are arranged in a rhombic shape (e.g., a substantially rhombic shape) as illustrated in FIG. 8 or a hexagonal structure (e.g., a substantially hexagonal structure) in which the emission areas are arranged in a hexagonal shape (e.g., a substantially hexagonal shape). PENTILE® is a duly registered trademark of Samsung Display Co., Ltd.

FIG. 9 is a schematic cross-sectional view illustrating an example of the display panel taken along the line I1-I1′ shown in FIG. 7.

Referring to FIG. 9, the display panel 100 may include a semiconductor backplane SBP, a light emitting element backplane EBP, the display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating (e.g., electrically insulating) films covering the plurality of pixel transistors PTR, and a plurality of contact terminals CTE electrically connected to the plurality of pixel transistors PTR, respectively. The plurality of pixel transistors PTR may be the first to sixth transistors T1 to T6 as described with reference to FIG. 5.

The semiconductor substrate SSUB may be a silicon substrate, a germanium substrate, or a silicon-germanium substrate. The semiconductor substrate SSUB may be a substrate doped with a first type (kind) impurity. A plurality of well regions WA may be arranged on the top surface of the semiconductor substrate SSUB. The plurality of well regions WA may be regions doped with a second type (kind) impurity. The second type (kind) impurity may be different from the first type (kind) impurity. For example, if (e.g., when) the first type (kind) impurity is a positive type (kind) (p-type (kind)) impurity, the second type (kind) impurity may be a negative type (kind) (n-type (kind)) impurity. In one or more embodiments, if (e.g., when) the first type (kind) impurity is an n-type (kind) impurity, the second type (kind) impurity may be a p-type (kind) impurity.

Each of the plurality of well regions WA may include a source region SA corresponding to the source electrode of the pixel transistor PTR, a drain region DA corresponding to the drain electrode thereof, and a channel region CH arranged between the source region SA and the drain region DA.

A lower insulating film BINS may be arranged between a gate electrode GE and the well region WA. A side insulating film SINS may be arranged on the side surface of the gate electrode GE. The side insulating film SINS may be arranged on the lower insulating film BINS.

Each of the source region SA and the drain region DA may be a region doped with the first type (kind) impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be arranged on one side of the gate electrode GE, and the drain region DA may be arranged on the other side of the gate electrode GE.

Each of the plurality of well regions WA may further include a first low-concentration impurity region LDD1 arranged between the channel region CH and the source region SA, and a second low-concentration impurity region LDD2 arranged between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be arranged on the semiconductor substrate SSUB. A second semiconductor insulating film SINS2 may be arranged on the first semiconductor insulating film SINS1.

The plurality of contact terminals CTE may be arranged on the second semiconductor insulating film SINS2. Each of the plurality of contact terminals CTE may be connected to any one selected from among the gate electrode GE, the source region SA, and the drain region DA of each of the pixel transistors PTR through a hole extending through the first semiconductor insulating film SINS1 and the second semiconductor insulating film SINS2. The plurality of contact terminals CTE may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them.

A third semiconductor insulating film SINS3 may be arranged on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed or composed of silicon carbonitride (SiCN) or a silicon oxide (e.g., SiOₓ, wherein 0<x≤2; e.g., SiO₂)-based inorganic film, but embodiments of the present disclosure are not limited thereto.

The semiconductor substrate SSUB may be replaced with a glass substrate and/or a polymer resin substrate, such as a polyimide substrate. In this case, thin film transistors may be arranged on the glass substrate and/or the polymer resin substrate. The glass substrate may be a rigid substrate that does not bend, and the polymer resin substrate may be a flexible substrate that may be bent or curved.

The light emitting element backplane EBP may include a plurality of conductive layers ML1 to ML8, a plurality of vias VA1 to VA9, and a plurality of interlayer insulating films INS1 to INS9.

The first to ninth interlayer insulating films INS1 to INS9 may serve to insulate (e.g., electrically insulate) the first to eighth conductive layers ML1 to ML8. The first to eighth conductive layers ML1 to ML8 may serve to connect the plurality of contact terminals CTE exposed from the semiconductor backplane SBP to thereby implement the circuit of the first sub-pixel SP1 as illustrated in FIG. 5.

For example, the first to sixth transistors T1 to T6 may be formed in the semiconductor backplane SBP, and the connection of the first to sixth transistors T1 to T6 and the first and second capacitors C1 and C2 may be accomplished through the first to eighth conductive layers ML1 to ML8. In one or more embodiments, the connection between the drain region corresponding to the drain electrode of the fourth transistor T4, the source region corresponding to the source electrode of the fifth transistor T5, and a first electrode AND of the light emitting element LE may also be accomplished through the first to eighth conductive layers ML1 to ML8.

The first to eighth conductive layers ML1 to ML8 and the first to eighth vias VA1 to VA8 may be formed or composed of substantially the same material. The first to eighth conductive layers ML1 to ML8 and the first to eighth vias VA1 to VA8 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. The first to eighth vias VA1 to VA8 may be made or composed of substantially the same material. First to eighth interlayer insulating films INS1 to INS8 may be formed or composed of a silicon oxide (e.g., SiOₓ, wherein 0<x≤2; e.g., SiO₂)-based inorganic layer, but embodiments of the present disclosure are not limited thereto.

A ninth interlayer insulating film INS9 may be arranged on the eighth interlayer insulating film INS8 and the eighth conductive layer ML8. The ninth interlayer insulating film INS9 may be formed or composed of a silicon oxide (e.g., SiOₓ, wherein 0<x≤2; e.g., SiO₂)-based inorganic film, but embodiments of the present disclosure are not limited thereto.

Each of the ninth vias VA9 may penetrate the ninth interlayer insulating film INS9 and be connected to the exposed eighth conductive layer ML8. The ninth vias VA9 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them.

The display element layer EML may be arranged on the light emitting element backplane EBP. The display element layer EML may include the tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be arranged on the ninth interlayer insulating film INS9. Each of the reflective electrodes RL may include at least one reflective electrode RL1, RL2, RL3, and RL4. For example, each of the reflective electrodes RL may include the first to fourth reflective electrodes RL1, RL2, RL3, and RL4 as illustrated in FIG. 9.

The first reflective electrodes RL1 may be arranged on the ninth interlayer insulating film INS9 and may be connected to the ninth via VA9. Each of the second reflective electrodes RL2 may be arranged on the first reflective electrode RL1 corresponding thereto. Each of the third reflective electrodes RL3 may be arranged on the second reflective electrode RL2 corresponding thereto. Each of the fourth reflective electrodes RL4 may be arranged on the third reflective electrode RL3 corresponding thereto.

Because the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the first reflective electrodes RL1 may contain titanium nitride (TiN), the second reflective electrodes RL2 may contain aluminum (Al), the third reflective electrodes RL3 may contain titanium nitride (TiN), and the fourth reflective electrodes RL4 may include titanium (Ti).

The tenth interlayer insulating film INS10 may be arranged on the ninth interlayer insulating film INS9. The tenth interlayer insulating film INS10 may be arranged between the reflective electrodes RL adjacent to each other. The tenth interlayer insulating film INS10 may be a film to flatten a stepped portion caused by the reflective electrodes RL. The eleventh interlayer insulating film INS11 may be arranged on the tenth interlayer insulating film INS10 and the reflective electrodes RL.

The tenth interlayer insulating film INS10 and the eleventh interlayer insulating film INS11 may be formed or composed of a silicon oxide (e.g., SiOₓ, wherein 0<x≤2; e.g., SiO₂)-based inorganic film, but embodiments of the present disclosure are not limited thereto.

The eleventh interlayer insulating film INS11 may be an optical auxiliary layer to adjust the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. For example, in order to adjust a distance from the reflective electrode RL to the second electrode CAT according to a main or predominant wavelength of light emitted from each of the first sub-pixel SP1, the second sub-pixel SP2, and the third sub-pixel SP3, the thickness of the eleventh interlayer insulating film INS11 may be set or predetermined for each of the first sub-pixel SP1, the second sub-pixel SP2, and the third sub-pixel SP3.

For example, as illustrated in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode RL in the first sub-pixel SP1 may be greater than the distance between the first electrode AND and the reflective electrode RL in the second sub-pixel SP2. In one or more embodiments, the distance between the first electrode AND and the reflective electrode RL in the second sub-pixel SP2 may be greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrode RL4. The tenth vias VA10 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be arranged on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the first electrode AND of each of the light emitting elements LE may be titanium nitride (TiN).

The pixel defining film PDL may be arranged on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is arranged.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be arranged on the edge of the first electrode AND of each of the light emitting elements LE, the second pixel defining film PDL2 may be arranged on the first pixel defining film PDL1, and the third pixel defining film PDL3 may be arranged on the second pixel defining film PDL2. The first pixel defining film PDL1, the second pixel defining film PDL2, and the third pixel defining film PDL3 may be formed or composed of a silicon oxide (e.g., SiOₓ, wherein 0<x≤2; e.g., SiO₂)-based inorganic film. In one or more embodiments, the first pixel defining film PDL1 and the third pixel defining film PDL3 may be formed or composed of a silicon nitride (e.g., SiNₓ, wherein 0<x≤2; e.g., Si₃N₄)-based inorganic film, whereas the second pixel defining film PDL2 may be formed or composed of a silicon oxide (e.g., SiOₓ, wherein 0<x≤2; e.g., SiO₂)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the thickness of a thin film formed or deposited on an inclined or vertical surface (such as a sidewall or a slope) to the thickness of the same film deposited on a horizontal or flat surface. Poor step coverage, e.g., a low ratio, may result in thinning or discontinuity of the film at the inclined portions, which increases the likelihood of film breakage or electrical failure. By designing the pixel defining layers with controlled step geometry and enhancing the deposition process, the likelihood of film discontinuity at these critical regions may be reduced, thereby improving or enhancing the reliability and encapsulation integrity of the device.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be arranged between the neighboring sub-pixels SP1, SP2, and SP3. Although FIG. 9 illustrates that two trenches TRC are arranged between the neighboring sub-pixels SP1, SP2, and SP3, embodiments of the present disclosure are not limited thereto.

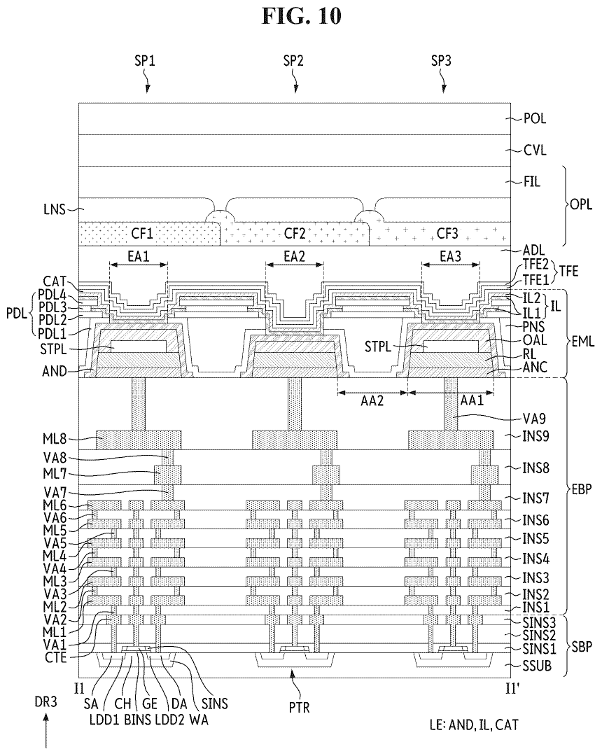

The light emitting stack IL may include a plurality of stack layers IL1, IL2, and IL3. FIG. 9 illustrates that the light emitting stack IL has a three-tandem structure including a first stack layer IL1, a second stack layer IL2, and a third stack layer IL3, but embodiments of the present disclosure are not limited thereto. For example, the light emitting stack IL may have a two-tandem structure including two stack layers as illustrated in FIG. 10.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer to supply charges to the second stack layer IL2 and supply electrons to the first stack layer IL1 may be arranged between the first stack layer IL1 and the second stack layer IL2. The first charge generation layer may include an N-type (kind) charge generation layer that supplies electrons to the first stack layer IL1 and a P-type (kind) charge generation layer that supplies holes to the second stack layer IL2. The N-type (kind) charge generation layer may include a dopant of a metal material.

A second charge generation layer to supply charges to the third stack layer IL3 and supply electrons to the second stack layer IL2 may be arranged between the second stack layer IL2 and the third stack layer IL3. The second charge generation layer may include an N-type (kind) charge generation layer that supplies electrons to the second stack layer IL2 and a P-type (kind) charge generation layer that supplies holes to the third stack layer IL3.

The first stack layer IL1 may be arranged on the first electrodes AND and the pixel defining film PDL, and a residual film RIL arranged on the bottom surface of each trench TRC may be substantially the same material as the first stack layer IL1. Due to the trench TRC, the first stack layer IL1 may be cut off between the neighboring sub-pixels SP1, SP2, and SP3. The second stack layer IL2 may be arranged on the first stack layer IL1. Due to the trench TRC, the second stack layer IL2 may be cut off between the neighboring sub-pixels SP1, SP2, and SP3. A cavity ESS or an empty space may be arranged between the residual film IL and the second stack layer IL2 in the trench TRC. The third stack layer IL3 may be arranged on the second stack layer IL2. The third stack layer IL3 may not be cut off by the trench TRC and may be arranged to cover the second stack layer IL2 in each of the trenches TRC.

In the three-tandem structure, each of the plurality of trenches TRC may be a structure to cut off the first to third hole transport layers, the first charge generation layer, and the second charge generation layer of the first to third stack layers IL1, IL2, and IL3 of the display element layer EML between the neighboring sub-pixels SP1, SP2, and SP3. In one or more embodiments, in the two-tandem structure, each of the plurality of trenches TRC may be a structure to cut off the charge generation layer and the lower stack layer arranged between the lower stack layer and the upper stack layer.

In order to stably or suitably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be arranged on the pixel defining film PDL.

In one or more embodiments, FIG. 9 illustrates that the light emitting stack IL that emits light is arranged in the first emission area EA1, the second emission area EA2, and the third emission area EA3, but embodiments of the present disclosure are not limited thereto. For example, instead of the light emitting stack IL, the first light emitting layer may be arranged in the first emission area EA1 and may not be provided in the second emission area EA2 and the third emission area EA3. Furthermore, the second light emitting layer may be arranged in the second emission area EA2 and may not be provided in the first emission area EA1 and the third emission area EA3. Furthermore, the third light emitting layer may be arranged in the third emission area EA3 and may not be provided in the first emission area EA1 and the second emission area EA2. In this case, first to third color filters CF1, CF2, and CF3 of the optical layer OPL may not be provided.

The second electrode CAT may be arranged on the light emitting stack IL. For example, the second electrode CAT may be arranged on the third stack layer IL3. The second electrode CAT may be formed or composed of a transparent conductive (e.g., electrically conductive) material (TCO), such as indium tin oxide (ITO) and/or indium zinc oxide (IZO) that can transmit light, or a semi-transmissive conductive (e.g., electrically conductive) material, such as magnesium (Mg), silver (Ag), or an alloy of Mg and Ag. If (e.g., when) the second electrode CAT is formed or composed of a semi-transmissive conductive (e.g., electrically conductive) material, the light emission efficiency may be improved or enhanced in each of the first to third sub-pixels SP1, SP2, and SP3 due to a micro-cavity effect.

The encapsulation layer TFE may be arranged on the display element layer EML. The encapsulation layer TFE may include at least one inorganic film TFE1 and TFE3 to prevent oxygen and/or moisture from permeating into the display element layer EML (or to reduce a degree to or occurrence of which oxygen and/or moisture permeate into the display element layer EML). The first encapsulation inorganic film TFE1 may be arranged on the second electrode CAT, and the second encapsulation inorganic film TFE3 may be arranged above the first encapsulation inorganic film TFE1. The first encapsulation inorganic film TFE1 and the second encapsulation inorganic film TFE3 may be formed or composed of two or more layers in which one or more inorganic films of silicon nitride (e.g., SiNₓ, wherein 0<x≤2; e.g., Si₃N₄), silicon oxynitride (e.g., SiOₓN_{y}, wherein 0<x≤2 and 0≤y≤2; e.g., SiON or Si₂N₂O), silicon oxide (e.g., SiOₓ, wherein 0<x≤2; e.g., SiO₂), titanium oxide (e.g., TiOₓ, wherein 0<x≤2; e.g., TiO₂), and aluminum oxide (e.g., AlOₓ, wherein 0<x≤2; e.g., Al₂O₃) layers are alternately stacked.

In one or more embodiments, the encapsulation layer TFE may include at least one organic film TFE2 to protect the display element layer EML from foreign substances, such as dust. The encapsulating organic film TFE2 may be arranged between the first encapsulating inorganic film TFE1 and the second encapsulating inorganic film TFE3. The encapsulation organic film TFE2 may be a monomer. In one or more embodiments, the encapsulation organic film TFE2 may be an organic film, such as an acryl resin, an epoxy resin, a phenolic resin, a polyamide resin, a polyimide resin, and/or the like.

An adhesive layer ADL may be a layer to bond the encapsulation layer TFE to the optical layer OPL. The adhesive layer ADL may be a double-sided adhesive member. In one or more embodiments, the adhesive layer ADL may be a transparent (e.g., substantially transparent) adhesive member, such as a transparent (e.g., substantially transparent) adhesive or a transparent (e.g., substantially transparent) adhesive resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be arranged on the adhesive layer ADL.

The first color filter CF1 may overlap the first emission area EA1 of the first sub-pixel SP1. The first color filter CF1 may be to transmit light of the first color, e.g., light of a blue wavelength band. The blue wavelength band may be in a range of about 370 nm to about 460 nm. Thus, the first color filter CF1 may be to transmit light of the first color among light emitted from the first emission area EA1.

The second color filter CF2 may overlap the second emission area EA2 of the second sub-pixel SP2. The second color filter CF2 may be to transmit light of the second color, e.g., light of a green wavelength band. The green wavelength band may be in a range of about 480 nm to about 560 nm. Thus, the second color filter CF2 may be to transmit light of the second color among light emitted from the second emission area EA2.

The third color filter CF3 may overlap the third emission area EA3 of the third sub-pixel SP3. The third color filter CF3 may be to transmit light of the third color, e.g., light of a red wavelength band. The red wavelength band may be in a range of about 600 nm to about 750 nm. Thus, the third color filter CF3 may be to transmit light of the third color among light emitted from the third emission area EA3.

The plurality of lenses LNS may be arranged on the first color filter CF1, the second color filter CF2, and the third color filter CF3, respectively. Each of the plurality of lenses LNS may be a structure to increase the proportion of light directed to the front of the display device 10. Each of the plurality of lenses LNS may have a cross-sectional shape that is convex in an upward direction.

The filling layer FIL may be arranged on the plurality of lenses LNS. The filling layer FIL may have a set or predetermined refractive index such that light travels in the third direction DR3 at an interface between the filling layer FIL and the plurality of lenses LNS. Further, the filling layer FIL may be a planarization layer. The filling layer FIL may be an organic film, such as an acrylic resin, an epoxy resin, a phenolic resin, a polyamide resin, and/or a polyimide resin.

The cover layer CVL may be arranged on the filling layer FIL. The cover layer CVL may be a glass substrate and/or a polymer resin. If (e.g., when) the cover layer CVL is a glass substrate, it may be attached onto the filling layer FIL. In this case, the filling layer FIL may serve to bond the cover layer CVL. If (e.g., when) the cover layer CVL is a glass substrate, it may serve as an encapsulation substrate. If (e.g., when) the cover layer CVL is a polymer resin, it may be directly applied onto the filling layer FIL.

The polarizing plate may be arranged on one surface of the cover layer CVL. The polarizing plate may be a structure to reduce or prevent visibility degradation caused by reflection of external light. The polarizing plate may include a linear polarizing plate and a phase retardation film. For example, the phase retardation film may be a λ/4 plate (quarter-wave plate), but embodiments of the present disclosure are not limited thereto. However, if (e.g., when) visibility degradation caused by reflection of external light is sufficiently or suitably overcome by the first to third color filters CF1, CF2, and CF3, the polarizing plate may not be provided.

FIG. 10 is a schematic cross-sectional view illustrating another example of the display panel taken along the line I1-I1′ shown in FIG. 7.

The embodiment of FIG. 10 differs from the embodiment of FIG. 9 in that the first electrode AND of each of the light emitting elements LE is in contact with and electrically connected to the side surface of a connection electrode ANC connected to the eighth conductive layer ML8. The embodiment of FIG. 10 also differs from the embodiment of FIG. 9 in that the trench TRC is not provided, and, instead, the third pixel defining film PDL3 and a fourth pixel defining film PDL4 have an eaves-shaped cross-sectional structure (e.g., a substantially eaves-shaped cross-sectional structure) or a mushroom-shaped cross-sectional structure (e.g., a substantially mushroom-shaped cross-sectional structure). In the embodiment of FIG. 10, redundant description of parts already described in the embodiment of FIG. 9 may not be provided.

Referring to FIG. 10, the plurality of connection electrodes ANC may be respectively arranged on first portions AA1 of the ninth interlayer insulating film INS9. Each of the plurality of connection electrodes ANC may be arranged on the first portion AA1 of the ninth interlayer insulating film INS9 corresponding thereto. A plurality of connection electrodes ANC may be formed or composed of any one selected from among copper (Cu), aluminum (Al), tungsten (W), molybdenum (Mo), chromium (Cr), gold (Au), titanium (Ti), nickel (Ni), and neodymium (Nd), an alloy including any one selected from among them, or a transparent (e.g., substantially transparent) conductive (e.g., electrically conductive) oxide. For example, the plurality of connection electrodes ANC may include titanium (Ti), titanium nitride (TiN), indium tin oxide (ITO), and/or indium zinc oxide (IZO), but embodiments of the present disclosure are limited thereto.

A plurality of reflective electrodes RL may be respectively arranged on the plurality of connection electrodes ANC. Each of the plurality of reflective electrodes RL may be arranged on the connection electrode ANC corresponding thereto. The plurality of reflective electrodes RL may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, each of the plurality of reflective electrodes RL may include aluminum (Al) having high reflectivity.

A plurality of optical auxiliary films OAL may be respectively arranged on the plurality of reflective electrodes RL. Each of the plurality of optical auxiliary films OAL may be arranged on the reflective electrode RL corresponding thereto. The plurality of optical auxiliary films OAL may be formed or composed of a silicon oxide (e.g., SiOₓ, wherein 0<x≤2; e.g., SiO₂)-based inorganic film, but embodiments of the present disclosure are not limited thereto.

In each of the first emission area EA1 and the third emission area EA3, a step layer STPL may be arranged on the reflective electrode RL, and the optical auxiliary film OAL may be arranged on the step layer STPL. In the second emission area EA2, only the optical auxiliary film OAL may be arranged on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set or predetermined in consideration of the wavelength and resonance distance of light emitted from the first stack layer IL1 of the light emitting stack IL, and the wavelength and resonance distance of light emitted from the second stack layer IL2 thereof.

Each of the light emitting elements LE may include the first electrode AND, a light emitting stack IL, and a second electrode CAT.

The first electrode AND of each of the light emitting elements LE may be arranged on the optical auxiliary film OAL corresponding thereto. Because the connection electrode ANC, the reflective electrode RL, and the optical auxiliary layer OAL are sequentially stacked, the first electrode AND of each of the light emitting elements LE may be arranged on the top surface and the side surface of the optical auxiliary layer OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to if (e.g., when) the first electrode AND of each of the light emitting elements LE is connected to the reflective electrode RL exposed through a through hole extending through the optical auxiliary film OAL, the number of mask processes may be reduced, thereby lowering manufacturing cost and increasing or enhancing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same.

In one or more embodiments, the thickness of the first portion AA1 of the ninth interlayer insulating film INS9 may be greater than the thickness of the second portion AA2 thereof. In this case, the side surface of the first portion AA1 of the ninth interlayer insulating film INS9 may be exposed, and the first electrode AND of each of the light emitting elements LE may be arranged on the exposed side surface of the first portion AA1 of the ninth interlayer insulating film INS9.

The first electrode AND of each of the light emitting elements LE may be formed or composed of any one selected from among copper (Cu), aluminum (Al), tungsten (W), molybdenum (Mo), chromium (Cr), gold (Au), titanium (Ti), nickel (Ni), and neodymium (Nd), an alloy including any one selected from among them, or a transparent (e.g., substantially transparent) conductive (e.g., electrically conductive) oxide. For example, the first electrode AND of each of the light emitting elements LE may include titanium (Ti), titanium nitride (TiN), indium tin oxide (ITO), and/or indium zinc oxide (IZO), but embodiments of the present disclosure are limited thereto.

The pixel defining film PDL may be arranged on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be arranged on the first electrode AND of each of the light emitting elements LE. For example, the first pixel defining film PDL1 may cover a part of the top surface of the first electrode AND arranged on the optical auxiliary film OAL. Further, the first pixel defining film PDL1 may cover the first electrode AND arranged on the side surface of the connection electrode ANC, the side surface of the reflective electrode RL, and the side surface of the optical auxiliary film OAL. The first pixel defining film PDL1 may be arranged on the top surface of the second portion AA2 of the ninth interlayer insulating film INS9.

A planarization film PNS may be a film to flatten the stepped portion caused by the connection electrode ANC, the reflective electrode RL, and the optical auxiliary film OAL.

The planarization film PNS may be arranged on the first pixel defining film PDL1 covering the first electrode AND arranged on the side surface of the connection electrode ANC, the side surface of the reflective electrode RL, and the side surface of the optical auxiliary film OAL. The planarization film PNS may be arranged on the first pixel defining film PDL1 arranged on the second portion AA2 of the ninth interlayer insulating film INS9.

The planarization film PNS may be arranged between the connection electrodes ANC adjacent in the first direction DR1 or the second direction DR2. The planarization film PNS may be arranged between the reflective electrodes RL adjacent in the first direction DR1 or the second direction DR2. The planarization film PNS may be arranged between the optical auxiliary films OAL adjacent in the first direction DR1 or the second direction DR2.

The step layer STPL may not be present in the second emission area EA2, whereas the step layer STPL may be present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 arranged on the top surface of the first electrode AND arranged in the second emission area EA2.

In contrast, the top surface of the planarization film PNS may be flatly connected to the top surface of the first pixel defining film PDL1 arranged on the top surface of the first electrode AND arranged in the first emission area EA1 and the third emission area EA3. For example, the planarization film PNS may not cover the top surface of the first pixel defining film PDL1 arranged on the top surface of the first electrode AND arranged in each of the first emission area EA1 and the third emission area EA3.

The second pixel defining film PDL2 may be arranged on the first pixel defining film PDL1 and the planarization film PNS, the third pixel defining film PDL3 may be arranged on the second pixel defining film PDL2, and the fourth pixel defining film PDL4 may be arranged on the third pixel defining film PDL3. The first pixel defining film PDL1 and the third pixel defining film PDL3 may be formed or composed of a silicon nitride (e.g., SiNₓ, wherein 0<x≤2; e.g., Si₃N₄)-based inorganic film, whereas the second pixel defining film PDL2, the fourth pixel defining film PDL4, and the planarization film PNS may be formed or composed of a silicon oxide (e.g., SiOₓ, wherein 0<x≤2; e.g., SiO₂)-based inorganic film. The first pixel defining film PDL1 may be formed or composed of a material different from a material of the planarization film PNS, and thus may serve as a stopper in a chemical mechanical polishing process for the planarization film PNS.

If (e.g., when) the planarization film PNS and the second pixel defining film PDL2 are both (e.g., simultaneously) formed as a silicon oxide (e.g., SiOₓ, wherein 0<x≤2; e.g., SiO₂)-based inorganic film, the planarization film PNS and the second pixel defining film PDL2 may be formed as a single film.

Because the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. For example, the third pixel defining film PDL3 and the fourth pixel defining film PDL4 may have an eaves-shaped cross-sectional structure (e.g., a substantially eaves-shaped cross-sectional structure) or a mushroom-shaped cross-sectional structure (e.g., a substantially mushroom-shaped cross-sectional structure).

The light emitting stack IL may be arranged on the first electrode AND and the pixel defining film PDL. The light emitting stack IL may include the first stack layer IL1 and the second stack layer IL2 that emit different lights. If (e.g., when) the light emitting stack IL has a two-tandem structure, one selected from the first stack layer IL1 and the second stack layer IL2 may be to emit light that includes the wavelength range of any one selected from among the first light, the second light, and the third light, and the other may be to emit light that includes the wavelength ranges of the other two lights. For example, the first stack layer IL1 may be to emit light that includes the wavelength range of the first light and the wavelength range of the third light, and the second stack layer IL2 may be to emit light that includes the wavelength range of the second light. Herein, the first light may be light of a blue wavelength band, the second light may be light of a green wavelength band, and the third light may be light of a red wavelength band.

A charge generation layer to supply charges to the second stack layer IL2 and supply electrons to the first stack layer IL1 may be arranged between the first stack layer IL1 and the second stack layer IL2. The charge generation layer may include an n-type (kind) charge generation layer that supplies electrons to the first stack layer IL1 and a p-type (kind) charge generation layer that supplies holes to the second stack layer IL2. The N-type (kind) charge generation layer may include a dopant of a metal material.

The first stack layer IL1 may not be formed on the bottom surface of the fourth pixel defining film PDL4 that is exposed without being covered by the third pixel defining film PDL3, and thus may be cut off by the eaves-shaped cross-sectional structure or the mushroom-shaped cross-sectional structure of the third pixel defining film PDL3 and the fourth pixel defining film PDL4. In this case, the first hole transport layer of the first stack layer IL1, and a charge generation layer arranged between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, it may be feasible to prevent a leakage current from flowing (or reduce a degree to or occurrence of which a leakage current flows) through the first hole transport layer of the first stack layer IL1, the second hole transport layer of the second stack layer IL2, and the charge generation layer between the adjacent emission areas EA1, EA2, and EA3. Accordingly, it may be feasible to prevent the light emitting stack IL in the adjacent emission areas EA1, EA2, and EA3 from emitting light other than the originally intended light (or reduce a degree to or occurrence of which the light emitting stack IL in the adjacent emission areas EA1, EA2, and EA3 emits light other than the originally intended light) due to the influence of the current as described herein.

Although FIG. 10 illustrates a two-tandem structure in which the light emitting stack IL includes two stack layers IL1 and IL2, embodiments of the present disclosure are not limited thereto. For example, the light emitting stack IL may have a three-tandem structure including three stack layers as illustrated in FIG. 9. In this case, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. In one or more embodiments, as illustrated in FIG. 9, the trench TRC extending through the first pixel defining film PDL1, the planarization film PNS, the second pixel defining film PDL2, and the third pixel defining film PDL3 may be added. In this case, the trench TRC may penetrate at least a part of the ninth interlayer insulating film INS9, but embodiments of the present disclosure are not limited thereto.

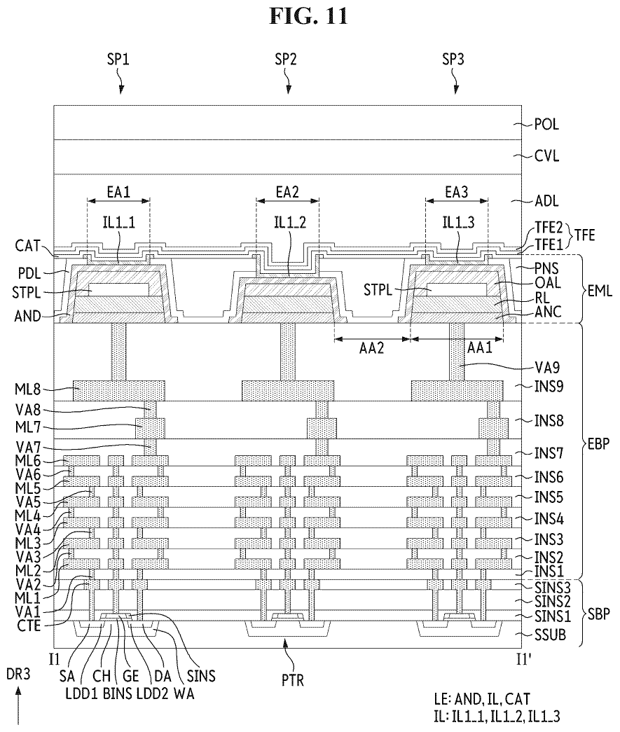

FIG. 11 is a schematic cross-sectional view illustrating another example of the display panel taken along the line I1-I1′ shown in FIG. 7.

The embodiment of FIG. 11 differs from the embodiment of FIG. 10 in that the light emitting elements LE have a single stack structure. In the embodiment of FIG. 11, redundant description of parts already described in the embodiment of FIG. 10 may not be provided.

Referring to FIG. 11, the pixel defining film PDL may be arranged on the ninth interlayer insulating film INS9 and the first electrodes AND, and the planarization film PNS may be arranged on the pixel defining film PDL. The planarization film PNS and the pixel defining film PDL may have openings exposing the first electrodes AND, and light emitting stack IL may be arranged on the first electrodes AND. For example, the pixel defining film PDL may have openings exposing the first electrodes AND in the first light emission area EA1, the second light emission area EA2 and the third light emission area EA3, and the planarization film PNS may have an opening exposing the first electrode AND in the second light emission area EA2. For example, the light emitting stack IL may include a first stack layer IL1_1, a second stack layer IL1_2, and a third stack layer IL1_3.

The first stack layer IL1_1 may be arranged on the first electrode AND exposed by the pixel defining film PDL in the first light emission area EA1. The first stack layer IL1_1 may also be arranged on a portion of the pixel defining film PDL. For example, the first stack layer IL1_1 may include a hole injecting layer, a hole transporting layer, a first light emitting layer, an electron transporting layer, and an electron injecting layer.

The second stack layer IL1_2 may be arranged on the first electrode AND exposed by the planarization film PNS and the pixel defining film PDL in the second light emission area EA2. The second stack layer IL1_2 may also be arranged on a portion of the planarization film PNS. For example, the second stack layer IL1_2 may include the hole injecting layer, the hole transporting layer, a second light emitting layer, the electron transporting layer, and the electron injecting layer.

The third stack layer IL1_3 may be arranged on the first electrode AND exposed by the pixel defining film PDL in the third light emission area EA3. The third stack layer IL1_3 may also be arranged on a portion of the pixel defining film PDL. For example, the third stack layer IL1_3 may include the hole injecting layer, the hole transporting layer, a third light emitting layer, the electron transporting layer, and the electron injecting layer.

The first stack layer IL1_1, the second stack layer IL1_2, and the third stack layer IL1_3 may be spaced and/or apart (e.g., spaced apart or separated) from each other, and thus the second to fourth pixel defining films PDL2, PDL3 and PDL4 utilized to separate the light emitting stack IL in the embodiment of FIG. 10 may not be provided.

The first stack IL1_1 of the first light emission area EA1 may be to emit first light, the second stack layer IL1_2 of the second light emission area EA2 may be to emit second light, and the third stack layer IL1_3 of the third light emission area EA3 may be to emit third light. Accordingly, the first to third color filters CF1, CF2 and CF3 of the optical layer OPL utilized in the embodiment of FIG. 9, the plurality of lenses LNS, and the filling layer FIL may not be provided.

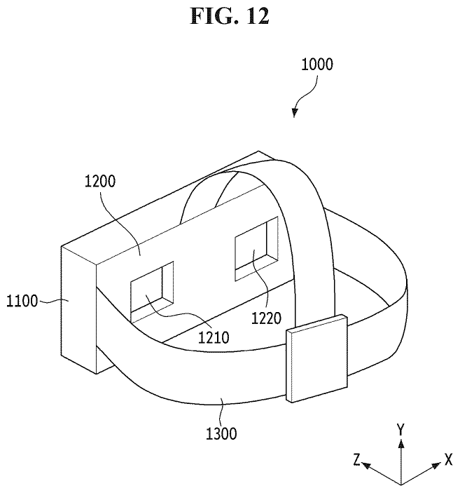

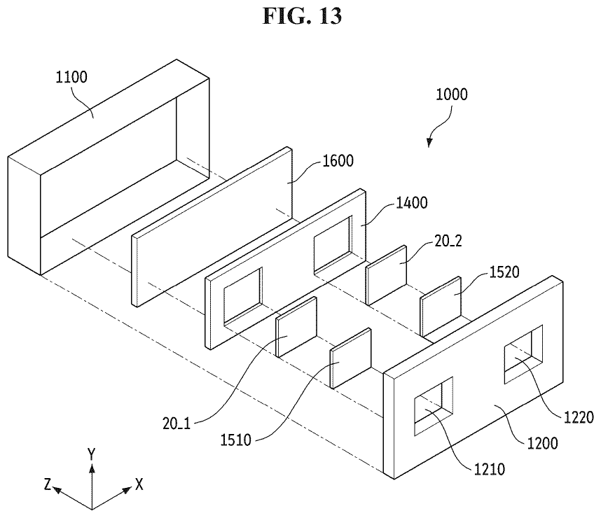

FIG. 12 is a schematic perspective view illustrating one example of a head mounted display. FIG. 13 is a schematic exploded perspective view illustrating the head mounted display as illustrated in FIG. 12.

Referring to FIGS. 12 and 13, a head mounted display 1000 according to one or more embodiments may include a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 may be to provide an image to the user's left eye, and the second display device 20_2 may be to provide an image to the user's right eye. Because each of the first display device 20_1 and the second display device 20_2 is substantially the same as the display device 20 as described in more detail in conjunction with FIGS. 3 to 11, the description of the first display device 20_1 and the second display device 20_2 may not be provided.

The first optical member 1510 may be arranged between the first display device 20_1 and the first eyepiece 1210. The second optical member 1520 may be arranged between the second display device 20_2 and the second eyepiece 1220. Each of the first optical member 1510 and the second optical member 1520 may include at least one convex lens.

The middle frame 1400 may be arranged between the first display device 20_1 and the control circuit board 1600 and between the second display device 20_2 and the control circuit board 1600. The middle frame 1400 may serve to support and fix the first display device 20_1, the second display device 20_2, and the control circuit board 1600.

The control circuit board 1600 may be arranged between the middle frame 1400 and the display device housing 1100. The control circuit board 1600 may be connected to the first display device 20_1 and the second display device 20_2 through the connector. The control circuit board 1600 may be to convert an image source inputted from the outside into the digital video data DATA and transmit the digital video data DATA to the first display device 20_1 and the second display device 20_2 through the connector.

The control circuit board 1600 may be to transmit the digital video data DATA corresponding to a left-eye image improved or optimized for the user's left eye to the first display device 20_1 and may be to transmit the digital video data DATA corresponding to a right-eye image improved or optimized for the user's right eye to the second display device 20_2. In one or more embodiments, the control circuit board 1600 may be to transmit substantially the same digital video data DATA to the first display device 20_1 and the second display device 20_2.

The display device housing 1100 may serve to accommodate the first display device 20_1, the second display device 20_2, the middle frame 1400, the first optical member 1510, the second optical member 1520, and the control circuit board 1600. The housing cover 1200 may be arranged to cover one open surface of the display device housing 1100. The housing cover 1200 may include the first eyepiece 1210 at which the user's left eye is located and the second eyepiece 1220 at which the user's right eye is located. FIGS. 12 and 13 illustrate that the first eyepiece 1210 and the second eyepiece 1220 are arranged separately, but embodiments of the present disclosure are not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

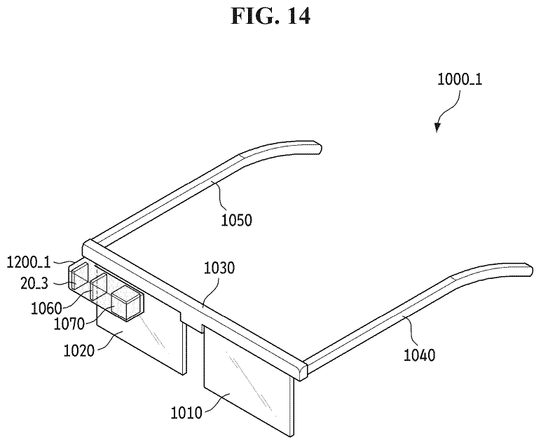

The head mounted band 1300 may serve to secure the display device housing 1100 to the user's head such that the first eyepiece 1210 and the second eyepiece 1220 of the housing cover 1200 remain located on the user's left and right eyes, respectively. If (e.g., when) the display device housing 1200 is implemented to be lightweight and compact, the head mounted display 1000 may be provided with, as illustrated in FIG. 14, an eyeglass frame instead of the head mounted band 1300.

FIG. 14 is a schematic perspective view illustrating another example of a head mounted display.

Referring to FIG. 14, a head mounted display 1000_1 according to one or more embodiments may be an eyeglasses-type (kind) display device in which a display device housing 1200_1 is implemented in a lightweight and compact manner. The head mounted display 1000_1 according to one or more embodiments may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060 and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 14 illustrates that the display device housing 1200_1 is arranged at the right end of the support frame 1030, but embodiments of the present disclosure are not limited thereto. For example, the display device housing 1200_1 may be arranged at the left end of the support frame 1030, and in this case, the image of the display device 20_3 may be provided to the user's left eye. In one or more embodiments, the display device housing 1200_1 may be arranged at both (e.g., simultaneously) the left and right ends of the support frame 1030, and in this case, the user may view the image displayed on the display device 20_3 through both (e.g., simultaneously) the left and right eyes.

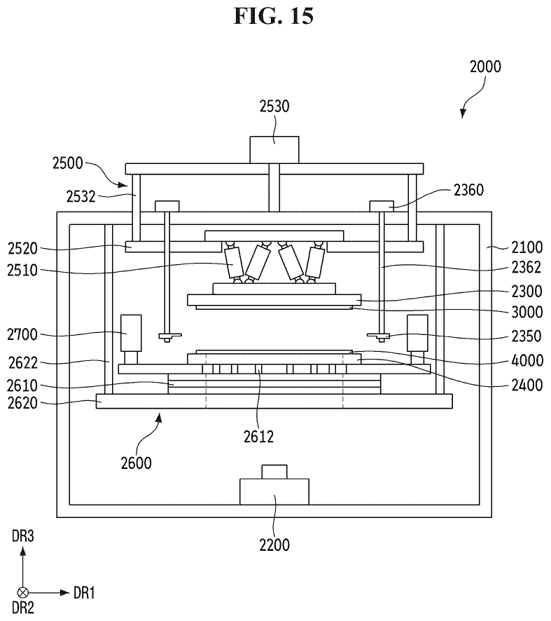

FIG. 15 is a schematic diagram illustrating a deposition mask and a deposition apparatus including the deposition mask according to one or more embodiments.

Referring to FIG. 15, a deposition apparatus 2000 according to one or more embodiments may be utilized to form a deposition material layer on a substrate. For example, the deposition apparatus 2000 according to one or more embodiments may be utilized to form light emitting layers on a backplane substrate 3000 (or display substrate) in a manufacturing process of the display panel 100 (see FIG. 3). For example, as illustrated in FIG. 11, the semiconductor backplane SBP and the light emitting element backplane EBP may be arranged on the backplane substrate 3000, and electrode patterns, e.g., the first electrodes AND functioning as anode electrodes, may be arranged on the light emitting element backplane EBP. In one or more embodiments, the pixel defining film PDL having openings that expose the first electrodes AND may be arranged on the light emitting element backplane EBP. As an example, the deposition apparatus 2000 may form first light emitting layers on the first electrodes AND of the first emission areas EA1. As another example, the deposition apparatus 2000 may form second light emitting layers on the first electrodes AND of the second emission areas EA2. As another example, the deposition apparatus 2000 may form third light emitting layers on the first electrodes AND of the third emission areas EA3.

The deposition apparatus 2000 may include a deposition source 2200 to provide a vapor deposition material on the backplane substrate 3000, a substrate chuck 2300 to support the backplane substrate 3000 to be opposite to (e.g., face) the deposition source 2200, and a mask chuck 2400 arranged between the deposition source 2200 and the substrate chuck 2300 to support a deposition mask 4000 to be opposite to (e.g., face) the backplane substrate 3000. The deposition source 2200, the substrate chuck 2300, and the mask chuck 2400 may be arranged in a process chamber (or an evaporation chamber) 2100.

A process chamber 2100 may have an internal space, and a deposition process to form a deposition material layer on the backplane substrate 3000 may be performed in the internal space of the process chamber 2100. The process chamber 2100 may be connected to a vacuum pump, and a vacuum atmosphere may be created in the internal space of the process chamber 2100 by the vacuum pump. An opening to load and/or unload the backplane substrate 3000 and the deposition mask 4000 may be provided on one wall of the process chamber 2100, and the opening may be opened and closed by a gate valve.

The deposition source 2200 may be arranged in the process chamber 2100, and a deposition material may be stored in the deposition source 2200. The deposition source 2200 may be to evaporate a deposition material, such as an organic material, an inorganic material, a conductive (e.g., electrically conductive) material, and/or the like, toward the backplane substrate 3000, and the evaporated deposition material may be deposited on the backplane substrate 3000 through the deposition mask 4000. For example, the deposition source 2200 may be to evaporate an organic light emitting material to form light emitting layers on the backplane substrate 3000 and may be provided with a heater to evaporate the organic light emitting material. The evaporated organic light emitting material may be deposited on electrode patterns on the backplane substrate 3000 through the deposition mask 4000, thereby forming light emitting layers on the electrode patterns of the backplane substrate 3000. As illustrated in FIG. 15, the deposition source 2200 may be arranged on the central portion of the bottom surface of the process chamber 2100, but the deposition source 2200 may be configured or arranged to move horizontally by a separate driver.

The substrate chuck 2300 may be arranged above the deposition source 2200 and may be to support the backplane substrate 3000 such that the backplane substrate 3000 is opposite to (e.g., faces) the deposition source 2200. For example, the substrate chuck 2300 may be an electrostatic chuck that holds the rear surface of the backplane substrate 3000 using an electrostatic force. For example, the electrode patterns, e.g., first electrodes AND, may be arranged on the front surface of the backplane substrate 3000, and the substrate chuck 2300 may be to hold the rear surface of the backplane substrate 3000 such that the front surface of the backplane substrate 3000 is (e.g., faces) downward, for example, is opposite to (e.g., faces) the deposition source 2200.

A plurality of lift fingers 2350 to load the backplane substrate 3000 onto the substrate chuck 2300 may be arranged in the process chamber 2100. The lift fingers 2350 may be arranged around the substrate chuck 2300 and the mask chuck 2400 and may be respectively moved vertically by finger drivers 2360. For example, three or four lift fingers 2350 may be arranged around the substrate chuck 2300 and the mask chuck 2400 and may be moved in the third direction DR3 by the finger drivers 2350.

The backplane substrate 3000 may be loaded into the process chamber 2100 by a transfer robot and may be transferred from the transfer robot onto the lift fingers 2350 under the substrate chuck 2300. In this case, the rear surface of the backplane substrate 3000 may be opposite to (e.g., face) the bottom surface of the substrate chuck 2300, and the lift fingers 2350 may be to support the front edge portions of the backplane substrate 3000. The finger drivers 2360 may be to raise the lift fingers 2350 such that the backplane substrate 3000 becomes adjacent to the bottom surface of the substrate chuck 2300, and the rear surface of the backplane substrate 3000 may be held on the bottom surface of the substrate chuck 2300 by an electrostatic force.

The finger drivers 2360 may be arranged on the upper lid of the process chamber 2100 and may be respectively connected to the lift fingers 2350 through driving shafts 2362 that extend vertically through the upper lid of the process chamber 2100. The finger drivers 2360 may be to vertically move the lift fingers 2350 to load or unload the backplane substrate 3000. In one or more embodiments, the finger drivers 2360 may be to rotate the lift fingers 2350 with respect to each of the driving shafts 2362. For example, the finger drivers 2360 may be to rotate the lift fingers 2350 such that the ends of the lift fingers 2350 do not overlap the substrate chuck 2300 and the mask chuck 2400, thereby enabling vertical movement of the lift fingers 2350. In one or more embodiments, the finger drivers 2360 may be to rotate the lift fingers 2350 such that the ends of the lift fingers 2350 overlap the edge portions of the backplane substrate 3000 to support the edge portions of the backplane substrate 3000.

The deposition mask 4000 may be loaded into the process chamber 2100 by the transfer robot and may be transferred onto the lift fingers 2350 above the mask chuck 2400. The edge portions of the deposition mask 4000 may be placed on the ends of the lift fingers 2350, and the finger drivers 2360 may be to lower the lift fingers 2350 to load the deposition mask 4000 onto the mask chuck 2300. In this case, recesses into which ends of lift fingers 2350 are inserted may be provided at the edge portions of the mask chuck 2400, and the finger drivers 2360 may be to rotate the lift fingers 2350 such that the lift fingers 2350 do not overlap the mask chuck 2400 after the deposition mask 4000 is loaded on the mask chuck 2400.

The mask chuck 2400 may be to support the edge portion of the deposition mask 4000. For example, the mask chuck 2400 may be an electrostatic chuck configured or arranged to hold the edge portion of the deposition mask 4000 using an electrostatic force. For example, the mask chuck 2400 may have a circular (e.g., substantially circular) opening to expose the deposition mask 4000 toward the deposition source 2200. For example, the mask chuck 2400 may have a disk shape (e.g., a substantially disk shape) or a quadrilateral plate shape (e.g., a substantially quadrilateral plate shape; e.g., in a form of plates) with a circular (e.g., substantially circular) opening.

The deposition apparatus 2000 may include a chuck driver to adjust the position and posture of the backplane substrate 3000 and the deposition mask 4000. For example, the deposition apparatus 2000 may include a substrate chuck driver 2500 to move the substrate chuck 2300 and a mask chuck driver 2600 to move the mask chuck 2400.

The substrate chuck driver 2500 may be to move the substrate chuck 2300 in the first direction DR1, the second direction DR2, and the third direction DR3 to adjust the position of the backplane substrate 3000. In this case, the first direction DR1 may be the first horizontal direction, the second direction DR2 may be the second horizontal direction normal (e.g., substantially perpendicular) to the first direction DR1, and the third direction DR3 may be the vertical direction. For example, the first direction DR1, the second direction DR2, and the third direction DR3 may be an X-axis direction, a Y-axis direction, and a Z-axis direction, respectively.

The substrate chuck driver 2500 may be to rotate the substrate chuck 2300 around the Z-axis to adjust the azimuth of the backplane substrate 3000, for example, the angle at which the backplane substrate 3000 is held on the bottom surface of the substrate chuck 2300. Further, the substrate chuck driver 2500 may be to rotate the substrate chuck 2300 around the X-axis and may also be to rotate the substrate chuck 2300 around the Y-axis in order to adjust the inclination of the backplane substrate 3000. For example, the substrate chuck driver 2500 may include a hexapod actuator 2510 that provides a motion of six degrees of freedom (X, Y, Z, θx, θy, and θz).

The substrate chuck driver 2500 may include a substrate stage 2520 to which the hexapod actuator 2510 is mounted, and a second actuator 2530 connected to the substrate stage 2520. The substrate stage 2520 may be arranged horizontally in the process chamber 2100, and the second actuator 2530 may be arranged above the process chamber 2100. The second actuator 2530 may be connected to the substrate stage 2520 by a plurality of driving shafts 2532 extending in the third direction DR3, e.g., the vertical direction (Z-axis direction) through the upper lid of the process chamber 2100 and may be to move the substrate stage 2520 in the central axis direction of the hexapod actuator 2510, e.g., the vertical direction. For example, the second actuator 2530 may be configured or arranged utilizing a brushless DC motor, a linear motor, a direct drive (DD) motor, and/or the like and may adjust the height of the substrate chuck 2300 to load or unload the backplane substrate 3000.

The hexapod actuator 2510 may include a first platform connected to the substrate chuck 2300, a second platform mounted to the substrate stage 2520, and six sub-actuators arranged between the first platform and the second platform. For example, the six sub-actuators may each be configured or arranged utilizing a brushless DC motor, a voice coil linear motor, a step motor, a direct drive (DD) motor, a servo motor, and/or the like and may be to move and rotate the first platform to adjust the horizontal position, vertical position, azimuth, and inclination of the backplane substrate 3000.

The mask chuck driver 2600 may be to move and rotate the mask chuck 2400 to adjust the horizontal position of the deposition mask 4000 and the azimuth angle of the deposition mask 4000, for example, the angle at which the deposition mask 4000 is placed on the mask chuck 2400. The mask chuck driver 2600 may be to move the mask chuck 2400 in a direction parallel to the deposition mask 4000 and rotate the mask chuck 2400 with respect to the central axis of the mask chuck 2400. For example, the mask chuck driver 2600 may be to move the mask chuck 2400 in the first direction DR1 (X-axis) and the second direction DR2 (Y-axis) and may be to rotate the mask chuck 2400 with respect to the third direction DR3 (Z-axis).

The mask chuck driver 2600 may include, e.g., a piezo actuator 2610 that provides a motion of three degrees of freedom (X, Y, and θz). The piezo actuator 2610 may have an opening to communicate with the circular opening of the mask chuck 2400. The mask chuck 2400 may be spaced upward from the piezo actuator 2610 by a selected distance. For example, a plurality of support members 2612 may be arranged on the piezo actuator 2610, and the mask chuck 2400 may be arranged on the plurality of support members 2612.

The mask chuck driver 2600 may include a mask stage 2620 that is horizontally arranged in the process chamber 2100 and supports the piezo actuator 2610. For example, the mask stage 2620 may have an opening that communicates with the opening of the piezo actuator 2610 and may be supported by a plurality of posts 2622 that are connected to the upper lid of the process chamber 2100.

After the backplane substrate 3000 and the deposition mask 4000 are loaded onto the substrate chuck 2300 and the mask chuck 2400, respectively, the second actuator 2530 may be to lower the substrate chuck 2300 such that the backplane substrate 3000 is brought adjacent to the deposition mask 4000. The hexapod actuator 2510 may be to adjust the gap between the backplane substrate 3000 and the deposition mask 4000 and may be to adjust the inclination of the substrate chuck 2300 to adjust the parallelism between the substrate chuck 2300 and the mask chuck 2400. For example, a plurality of gap sensors to measure the gap between the substrate chuck 2300 and the mask chuck 2400 may be mounted at the substrate chuck 2300, and the hexapod actuator 2510 may be to adjust the parallelism between the substrate chuck 2300 and the mask chuck 2400 based on the measured values of the gap sensors.

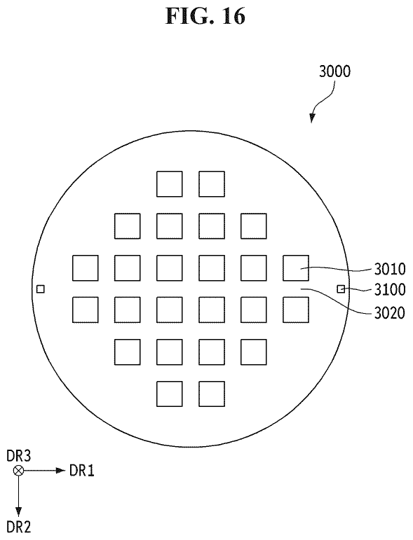

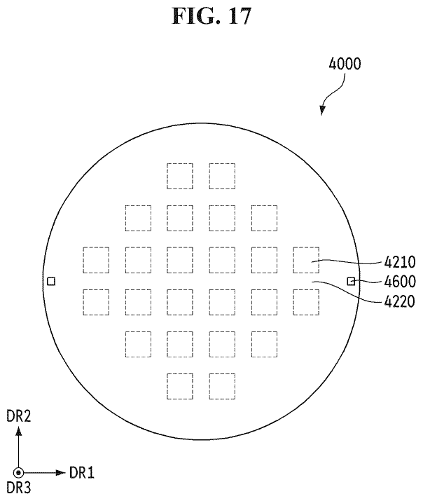

The deposition apparatus 2000 may include cameras 2700 to acquire positional information of the backplane substrate 3000 and the deposition mask 4000 to align between the backplane substrate 3000 and the deposition mask 4000. For example, substrate alignment keys 3100 (see FIG. 16) may be arranged on the edge portions of the backplane substrate 3000, and mask alignment keys 4600 (see FIG. 17) may be arranged on the edge portions of the deposition mask 4000. The deposition apparatus 2000 may include the cameras 2700 to detect the substrate alignment keys 3100 and the mask alignment keys 4600, and the substrate chuck driver 2500 or the mask chuck driver 2600 may be to align the backplane substrate 3000 and the deposition mask 4000 with each other based on the positional information of the substrate alignment keys 3100 and the mask alignment keys 4600 obtained by the cameras 2700.

As described in one or more embodiments, after the parallelism adjustment between the substrate chuck 2300 and the mask chuck 2400 and the positional alignment between the backplane substrate 3000 and the deposition mask 4000 are performed, the backplane substrate 3000 may be positioned on the deposition mask 4000. For example, the hexapod actuator 2510 may be to adjust the height of the substrate chuck 2300 such that the gap between the backplane substrate 3000 and the deposition mask 4000 becomes a selected gap, e.g., a gap of several μm. For another example, the hexapod actuator 2510 may be to adjust the height of the substrate chuck 2300 such that the backplane substrate 3000 is brought into contact with the deposition mask 4000.

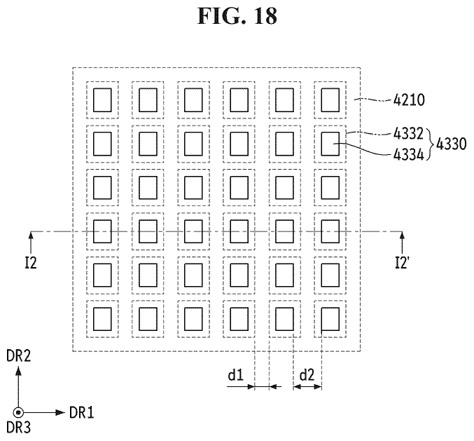

After the backplane substrate 3000 is positioned on the deposition mask 4000, the deposition source 2200 may be to provide a vapor deposition material onto the backplane substrate 3000 through the deposition mask 4000, thereby forming a deposition material layer on the backplane substrate 3000. For example, the deposition source 2200 may be to provide a vapor light emitting material to form light emitting layers on the backplane substrate 3000, and the vapor light emitting material may be deposited on the electrode patterns of the backplane substrate 3000 through pixel openings 4212 (see FIG. 18) of the deposition mask 4000.

FIG. 16 is a schematic bottom view illustrating the backplane substrate as illustrated in FIG. 15.

Referring to FIG. 16, the backplane substrate 3000 may include a plurality of display cell regions 3010 and a scribe lane region 3020 arranged between the display cell regions 3010. The display cell regions 3010 may be arranged in a matrix form along the first direction DR1 and the second direction DR2 as illustrated in FIG. 16, and may be individualized into the display panels 100 (see FIG. 3) by a dicing process after the display manufacturing process is completed. For example, the first direction DR1 may be a first horizontal direction, and the second direction DR2 may be a second horizontal direction normal (e.g., substantially perpendicular) to the first direction DR1. In one or more embodiments, each of the display cell regions 3010 may have, for example, a quadrilateral shape (e.g., a substantially quadrilateral shape) as illustrated in the drawing.

For example, each of the display cell regions 3010 may include the semiconductor backplane SBP and the light emitting element backplane EBP arranged on the semiconductor backplane SBP, as illustrated in FIG. 11. In one or more embodiments, a plurality of electrode patterns, e.g., the plurality of first electrodes AND, may be arranged on the light emitting element backplane EBP, and the pixel defining film PDL having openings that expose the first electrodes AND may be arranged on the light emitting element backplane EBP and the first electrodes AND. In this case, the electrode patterns of the display cell regions 3010 may be arranged on the front surface of the backplane substrate 3000, and the substrate chuck 2300 may be to hold the rear surface of the backplane substrate 3000 such that the electrode patterns of the display cell regions 3010 are (e.g., face) downward, e.g., are opposite to (e.g., face) the deposition source 2200.

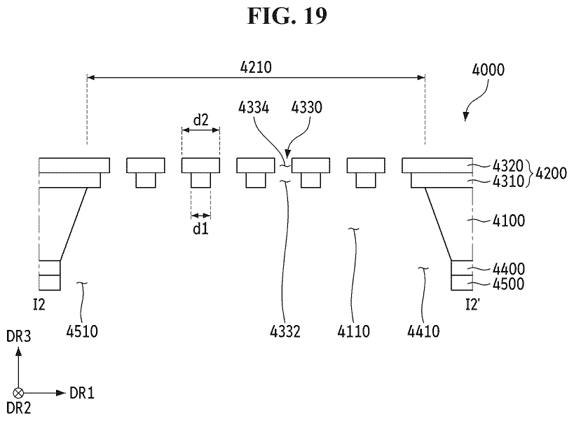

FIG. 17 is a schematic plan view illustrating the deposition mask as illustrated in FIG. 15. FIG. 18 is a schematic plan view illustrating the mask cell regions as illustrated in FIG. 17. FIG. 19 is a schematic cross-sectional view taken along the line I2-I2′ shown in FIG. 18.

Referring to FIGS. 17 to 19, the deposition mask 4000 may include mask cell regions 4210 respectively corresponding to the display cell regions 3010 of the backplane substrate 3000, and a grid region 4220 corresponding to the scribe lane region 3020 of the backplane substrate 3000. Each of the mask cell regions 4210 may have a plurality of pixel openings 4330 exposing the electrode patterns of the backplane substrate 3000 in a deposition process. For example, if (e.g., when) the backplane substrate 3000 is positioned on the deposition mask 4000 in the deposition process, the electrode patterns, e.g., the first electrodes AND, of the backplane substrate 3000 may be positioned on the pixel openings 4330 of the deposition mask 4000, and accordingly, the first electrodes AND may be exposed toward the deposition source 2200 through the pixel openings 4330.

According to one or more embodiments, the deposition mask 4000 may include a mask substrate 4100 and the membrane 4200 arranged on the mask substrate 4100. According to one or more embodiments, the membrane 4200 may include the plurality of mask cell regions 4210 and the grid region 4220 around (e.g., surrounding) the mask cell regions 4210, and each of the mask cell regions 4210 may have the plurality of pixel openings 4330.

According to one or more embodiments, the membrane 4200 may include a first membrane 4310 arranged on the mask substrate 4100 and a second membrane 4320 arranged on the first membrane 4310. According to one or more embodiments, the pixel openings 4330 may be formed to penetrate the membrane 4200. For example, the pixel openings 4330 may include first pixel openings 4332 extending through the first membrane 4310 and second pixel openings 4334 extending through the second membrane 4320.

According to one or more embodiments, the mask substrate 4100 may have cell openings 4110 respectively corresponding to the mask cell regions 4210. For example, the mask cell regions 4210 may be regions exposed through the cell openings 4110, and the pixel openings 4330 may be to communicate with the cell openings 4110. For example, the mask cell regions 4210 of the membrane 4200 may be exposed toward the deposition source 2200 through the cell openings 4110 of the mask substrate 4100. In this case, while performing the deposition process, the vapor deposition material provided from the deposition source 2200 may be deposited on the first electrodes AND of the backplane substrate 3000 through the cell openings 4110 and the pixel openings 4330.

As illustrated in FIG. 17, the mask cell regions 4210 may be arranged in a matrix form along the first direction DR1 and the second direction DR2. For example, the first direction DR1 may be the first horizontal direction, and the second direction DR2 may be the second horizontal direction normal (e.g., substantially perpendicular) to the first direction DR1. The mask cell regions 4210 may have, for example, a quadrilateral shape (e.g., a substantially quadrilateral shape) as illustrated in the drawing, and the pixel openings 4330 may be arranged to correspond to the first electrodes AND of any one selected from among the first emission areas EA1, the second emission areas EA2, and the third emission areas EA3.

According to one or more embodiments, the mask substrate 4100 may include single crystal silicon. For example, a single crystal silicon substrate having a thickness in the range of about 700 μm to about 800 μm, e.g., about 725 μm or about 775 μm, may be utilized as the mask substrate 4100.

According to one or more embodiments, the second membrane 4320 may include silicon nitride (e.g., SiNₓ, wherein 0<x≤2; e.g., Si₃N₄) having residual tensile stress. For example, the second membrane 4320 may include stoichiometric silicon nitride (Si₃N₄). In another example, the second membrane 4320 may include silicon-rich silicon nitride (Si-rich SiN) having a higher silicon content (e.g., amount) than stoichiometric silicon nitride. In this case, the second membrane 4320 may have a smaller residual tensile stress than if (e.g., when) it includes stoichiometric silicon nitride.

According to one or more embodiments, the first membrane 4310 may include silicon oxide (e.g., SiOₓ, wherein 0<x≤2; e.g., SiO₂) having residual compressive stress. For example, the first membrane 4310 may be formed on the mask substrate 4100 by a thermal oxidation process and/or a chemical vapor deposition (CVD) process, and the second membrane 4320 may be formed on the first membrane 4310 by a low pressure chemical vapor deposition (LPCVD) process.

If (e.g., when) the first membrane 4310 is not provided, the second membrane 4320 may be deformed due to the residual tensile stress. For example, if (e.g., when) the first membrane 4310 is not provided, the mask cell regions 4210 may be deformed concavely toward the cell openings 4110 due to the residual tensile stress. According to one or more embodiments, the first membrane 4310 may be utilized to improve or enhance cell warpage in which the mask cell regions 4210 are deformed concavely toward the cell openings 4110. For example, the first membrane 4310 may prevent or reduce the occurrence of smile-shaped warpage in the mask cell regions 4210. For example, the first membrane 4310 may have a thickness in a range of about 0.2 μm to about 2 μm, and the second membrane 4320 may have a thickness in a range of about 0.3 μm to about 3 μm.

According to one or more embodiments, the cell warpage of the deposition mask 4000 may be reduced by the residual compressive stress of the first membrane 4310 and the residual tensile stress of the second membrane 4320, and thus the distance between the backplane substrate 3000 and the deposition mask 4000 may become more substantially uniform. As a result, the pixel position accuracy (PPA) and size uniformity of the light emitting layers formed on the backplane substrate 3000 by the deposition process may be significantly or substantially improved or enhanced.

According to one or more embodiments, a distance d1 between the first pixel openings 4332 may be smaller than a distance d2 between the second pixel openings 4334. For example, the distance d1 between the first pixel openings 4332 may range from about 0.2 times to about 0.8 times the distance d2 between the second pixel openings 4334. Accordingly, the first pixel openings 4332 may have a greater width than the second pixel openings 4334. As a result, the amount of deposition material blocked by the first membrane 4310 during the deposition process may be reduced, and shadow regions generated by the first membrane 4310 may be reduced.

During the deposition process, the deposition material may be deposited on the deposition mask 4000, and a deposition material layer formed on the deposition mask 4000 may be removed by an ultrasonic cleaning process. For example, an ultrasonic cleaning process utilizing an N-methyl-2-pyrrolidone (NMP) cleaning solution may be performed, and ultrasonic vibration may be applied to the deposition mask 4000 during the ultrasonic cleaning process. According to one or more embodiments, the rigidity of the mask cell regions 4210 may be increased by the first membrane 4310, and accordingly, damage to the mask cell regions 4210 due to ultrasonic vibration may be prevented or reduced during the ultrasonic cleaning process.

According to one or more embodiments, the first membrane 4310 may include metal having residual compressive stress. For example, the first membrane 4310 may include a material containing metal, such as nickel (Ni), titanium (Ti), titanium nitride (TiN), tungsten (W), tungsten nitride (WN), and/or aluminum oxide (e.g., AlOₓ, wherein 0<x≤2; e.g., Al₂O₃) and may be formed on the mask substrate 4100 by a physical vapor deposition process, such as a sputtering process.

In one or more embodiments, the second membrane 4320 may include metal having residual compressive stress. For example, the second membrane 4320 may include a material containing metal, such as nickel (Ni), titanium (Ti), titanium nitride (TiN), tungsten (W), tungsten nitride (WN), and/or aluminum oxide (e.g., AlOₓ, wherein 0<x≤2; e.g., Al₂O₃). In this case, the first membrane 4310 may include silicon nitride (e.g., SiNₓ, wherein 0<x≤2; e.g., Si₃N₄) having residual tensile stress. For example, the first membrane 4310 may include stoichiometric silicon nitride (Si₃N₄) and/or silicon-rich silicon nitride. For example, the first membrane 4310 may be formed on the mask substrate 4100 by an LPCVD process, and the second membrane 4320 may be formed on the first membrane 4310 by a physical vapor deposition process, such as a sputtering process.

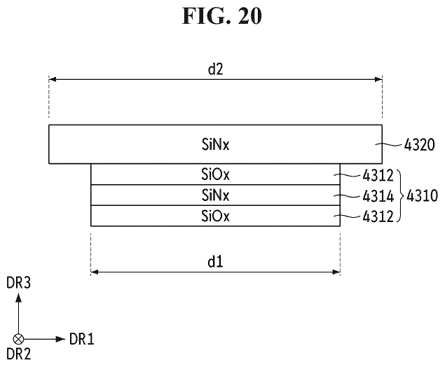

FIG. 20 is a schematic enlarged cross-sectional view illustrating another example of the membrane as illustrated in FIG. 19.

Referring to FIG. 20, the first membrane 4310 may be a composite film in which a plurality of silicon oxide films 4312 and at least one silicon nitride film 4314 are alternately stacked. The silicon oxide films 4312 and the silicon nitride film 4314 may be alternately formed by an LPCVD process, thereby reducing the cell warpage of the deposition mask 4000 and improving or enhancing the rigidity of the mask cell regions 4210.

Referring back to FIG. 19, the deposition mask 4000 may include an intermediate inorganic film 4400 and a rear inorganic film 4500. According to one or more embodiments, the membrane 4200 may be arranged on the front surface of the mask substrate 4100, and the intermediate inorganic film 4400 and the rear inorganic film 4500 may be arranged on the rear surface of the mask substrate 4100. For example, the intermediate inorganic film 4400 may be arranged on the rear surface of the mask substrate 4100, and the rear inorganic film 4500 may be arranged on the intermediate inorganic film 4400.

According to one or more embodiments, the intermediate inorganic film 4400 and the rear inorganic film 4500 may have intermediate openings 4410 and rear openings 4510 to communicate with the cell openings 4110, respectively, and the intermediate inorganic film 4400 and the rear inorganic film 4500 may be to function as an etching mask in an etching process to form the cell openings 4110. In this case, the mask cell regions 4210 may be exposed toward the deposition source 2200 through the cell openings 4110, the intermediate openings 4410, and the rear openings 4510. In one or more embodiments, the vapor deposition material provided from the deposition source 2200 during the deposition process may be deposited on the first electrodes AND of the backplane substrate 3000 through the rear openings 4510, the intermediate openings 4410, the cell openings 4110, and the pixel openings 4330.

According to one or more embodiments, in order to prevent or reduce global warpage in which the entire deposition mask 4000 is deformed, the intermediate inorganic film 4400 may include substantially the same material as the first membrane 4310, and the rear inorganic film 4500 may include substantially the same material as the second membrane 4320. For example, the intermediate inorganic film 4400 may include silicon oxide (e.g., SiOₓ, wherein 0<x≤2; e.g., SiO₂) and may be formed concurrently (e.g., simultaneously) with the first membrane 4310 by a thermal oxidation process or a CVD process. The rear inorganic film 4500 may include silicon nitride (e.g., SiNₓ, wherein 0<x≤2; e.g., Si₃N₄) and may be formed concurrently (e.g., simultaneously) with the second membrane 4320 by an LPCVD process.

According to one or more embodiments, the cell openings 4110 may be formed by an etching process utilizing the intermediate inorganic film 4400 and the rear inorganic film 4500 as etching masks. For example, the cell openings 4110 may be formed by a wet etching process utilizing an etchant, such as a tetramethylammonium hydroxide (TMAH) solution and/or a potassium hydroxide (KOH) solution. For another example, the cell openings 4110 may be formed by a deep reactive ion etching (DRIE) process and/or a cryogenic etching process.

According to one or more embodiments, if (e.g., when) the first membrane 4310 includes metal having residual compressive stress and the second membrane 4320 includes silicon nitride (e.g., SiNₓ, wherein 0<x≤2; e.g., Si₃N₄) having residual tensile stress, the intermediate inorganic film 4400 may not be provided, and the rear inorganic film 4500 having residual tensile stress may be formed on the rear surface of the mask substrate 4100. For example, in order to reduce the global warpage of the deposition mask 4000, the rear inorganic film 4500 may include silicon nitride (e.g., SiNₓ, wherein 0<x≤2; e.g., Si₃N₄) having residual tensile stress. For example, the rear inorganic film 4500 may include stoichiometric silicon nitride (Si₃N₄) and/or silicon-rich silicon nitride and may be formed on the rear surface of the mask substrate 4100 by an LPCVD process to have a smaller thickness than the second membrane 4320. In this case, the thickness of the rear inorganic film 4500 may be determined such that the force applied to the mask substrate 4100 by the membrane 4200 and the force applied to the mask substrate 4100 by the rear inorganic film 4500 are in balance with each other.

In one or more embodiments, if (e.g., when) the first membrane 4310 includes silicon nitride (e.g., SiNₓ, wherein 0<x≤2; e.g., Si₃N₄) having residual tensile stress, and the second membrane 4320 includes metal having residual compressive stress, the intermediate inorganic film 4400 may not be provided, and the rear inorganic film 4500 having residual compressive stress may be formed on the rear surface of the mask substrate 4100. For example, in order to reduce the global warpage of the deposition mask 4000, the rear inorganic film 4500 may include silicon oxide (e.g., SiOₓ, wherein 0<x≤2; e.g., SiO₂) having residual compressive stress and may be formed on the rear surface of the mask substrate 4100 by a CVD process. In this case, the thickness of the rear inorganic film 4500 may be determined such that the force applied to the mask substrate 4100 by the membrane 4200 and the force applied to the mask substrate 4100 by the rear inorganic film 4500 are in balance with each other.

In one or more embodiments, as illustrated in FIG. 20, if (e.g., when) a composite film in which the plurality of silicon oxide films 4312 and the at least one silicon nitride film 4314 are alternately stacked is utilized as the first membrane 4310, and the second membrane 4320 includes silicon nitride (e.g., SiNₓ, wherein 0<x≤2; e.g., Si₃N₄) having residual tensile stress, the intermediate inorganic film 4400 may not be provided, and the rear inorganic film 4500 having residual tensile stress may be formed on the rear surface of the mask substrate 4100. For example, in order to reduce the global warpage of the deposition mask 4000, the rear inorganic film 4500 may include silicon nitride (e.g., SiNₓ, wherein 0<x≤2; e.g., Si₃N₄) having residual tensile stress. For example, the rear inorganic film 4500 may include stoichiometric silicon nitride (Si₃N₄) and/or silicon-rich silicon nitride and may be formed on the rear surface of the mask substrate 4100 by an LPCVD process to have a smaller thickness than the second membrane 4320. In this case, the thickness of the rear inorganic film 4500 may be determined such that the force applied to the mask substrate 4100 by the membrane 4200 and the force applied to the mask substrate 4100 by the rear inorganic film 4500 are in balance with each other.

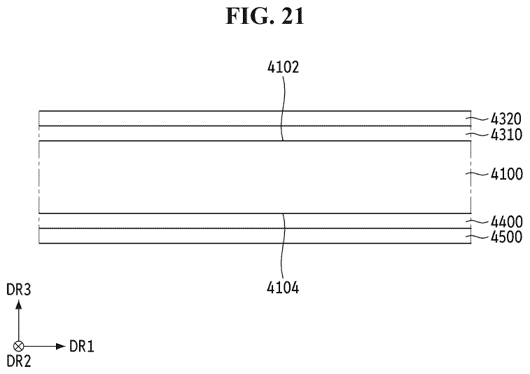

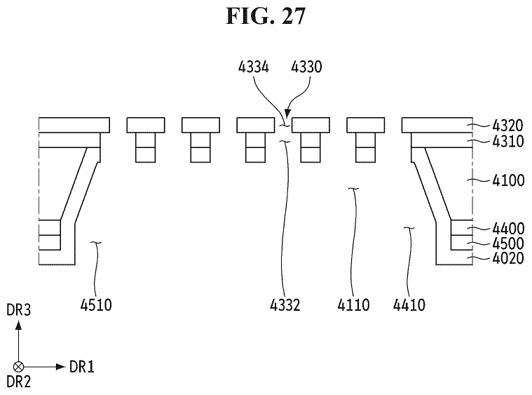

FIGS. 21 to 27 are schematic cross-sectional views illustrating a method of manufacturing a deposition mask according to one or more embodiments of the present disclosure.

Referring to FIG. 21, the first membrane 4310 having residual compressive stress may be formed on the mask substrate 4100. According to one or more embodiments, the mask substrate 4100 may include single crystal silicon. For example, a single crystal silicon substrate having a thickness in the range of about 700 μm to about 800 μm, e.g., about 725 μm or about 775 μm, may be utilized as the mask substrate 4100. According to one or more embodiments, the first membrane 4310 may include silicon oxide (e.g., SiOₓ, wherein 0<x≤2; e.g., SiO₂) and may be formed with a thickness in the range of about 0.2 μm to about 2 μm on the front surface 4102 of the mask substrate 4100 by a thermal oxidation process or a CVD process.

According to one or more embodiments, the intermediate inorganic film 4400 may be formed on a rear surface 4104 of the mask substrate 4100. According to one or more embodiments, the intermediate inorganic film 4400 may include silicon oxide (e.g., SiOₓ, wherein 0<x≤2; e.g., SiO₂) and may be formed by a thermal oxidation process and/or a CVD process. For example, the first membrane 4310 and the intermediate inorganic film 4400 may be formed concurrently (e.g., simultaneously) by a thermal oxidation process and/or a CVD process. In this case, the intermediate inorganic film 4400 may have substantially the same thickness as the first membrane 4310.

According to one or more embodiments, the second membrane 4320 having residual tensile stress may be formed on the first membrane 4310. According to one or more embodiments, the second membrane 4320 may include silicon nitride (e.g., SiNₓ, wherein 0<x≤2; e.g., Si₃N₄) having residual tensile stress. For example, the second membrane 4320 may include stoichiometric silicon nitride (Si₃N₄) and/or silicon-rich silicon nitride and may be formed on the first membrane 4310 by an LPCVD process. For example, a silicon source gas, such as monosilane (SiH₄) and/or dichlorosilane (DCS) (SiH₂Cl₂), and a nitrogen source gas, such as N₂ and/or NH₃, may be supplied onto the first membrane 4310, and the second membrane 4320 may be formed with a thickness in the range of about 0.3 μm to about 3 μm by a reaction between the silicon source gas and the nitrogen source gas.

According to one or more embodiments, the rear inorganic film 4500 may be formed on the second intermediate inorganic film 4400. According to one or more embodiments, the rear inorganic film 4500 may include silicon nitride (e.g., SiNₓ, wherein 0<x≤2; e.g., Si₃N₄) and may be formed by a LPCVD process. For example, the second membrane 4320 and the rear inorganic film 4500 may be formed concurrently (e.g., simultaneously) by the LPCVD process. In this case, the rear inorganic film 4500 may have substantially the same thickness as the second membrane 4320.

According to one or more embodiments, the first membrane 4310 may include metal having residual compressive stress. For example, the first membrane 4310 may include a material containing metal, such as nickel (Ni), titanium (Ti), titanium nitride (TiN), tungsten (W), tungsten nitride (WN), and/or aluminum oxide (e.g., AlOₓ, wherein 0<x≤2; e.g., Al₂O₃), and may be formed on the front surface 4102 of the mask substrate 4100 by a physical vapor deposition process, such as a sputtering process. In this case, the intermediate inorganic film 4400 may not be provided, and the rear inorganic film 4500 may include silicon nitride (e.g., SiNₓ, wherein 0<x≤2; e.g., Si₃N₄) having residual tensile stress. In one or more embodiments, the rear inorganic film 4500 may be formed on the rear surface 4104 of the mask substrate 4100 separately from the second membrane 4320 by an LPCVD process.

In one or more embodiments, the first membrane 4310 may include silicon nitride (e.g., SiNₓ, wherein 0<x≤2; e.g., Si₃N₄) having residual tensile stress, and the second membrane 4320 may include metal having residual compressive stress. For example, the first membrane 4310 may include stoichiometric silicon nitride (Si₃N₄) and/or silicon-rich silicon nitride, and the second membrane may include a material containing metal, such as nickel (Ni), titanium (Ti), titanium nitride (TiN), tungsten (W), tungsten nitride (WN), and/or aluminum oxide (e.g., AlOₓ, wherein 0<x≤2; e.g., Al₂O₃). For example, the first membrane 4310 may be formed by an LPCVD process, and the second membrane 4320 may be formed by a physical vapor deposition process, such as a sputtering process. In this case, the intermediate inorganic film 4400 may not be provided, and the rear inorganic film 4500 may include silicon oxide (e.g., SiOₓ, wherein 0<x≤2; e.g., SiO₂) having residual compressive stress. For example, the rear inorganic film 4500 may be formed on the rear surface 4104 of the mask substrate 4100 by a CVD process. For example, a silicon source gas, such as monosilane (SiH₄) and/or dichlorosilane (DCS), and an oxygen source gas, such as O₂, NO, and/or N₂O, may be supplied to the rear surface 4104 of the mask substrate 4100, and the rear inorganic film 4500 may be formed on the rear surface 4104 of the mask substrate 4100 by a reaction between the silicon source gas and the oxygen source gas.

In one or more embodiments, as illustrated in FIG. 20, the first membrane 4310 may be a composite film in which the plurality of silicon oxide films 4312 and the at least one silicon nitride film 4314 are alternately stacked. For example, the composite film may be formed by a CVD process utilizing a silicon source gas, such as monosilane (SiH₄) and/or dichlorosilane (DCS), an oxygen source gas, such as O₂, NO, and/or N₂O, and a nitrogen source gas, such as N₂ and/or NH₃. For example, the silicon oxide film 4312 may be formed using the silicon source gas and the oxygen source gas, and the silicon nitride film 4314 may be formed using the silicon source gas and the nitrogen source gas. In this case, the intermediate inorganic film 4400 may not be provided, and the rear inorganic film 4500 may include silicon nitride (e.g., SiNₓ, wherein 0<x≤2; e.g., Si₃N₄) having residual tensile stress. In one or more embodiments, the rear inorganic film 4500 may be formed on the rear surface 4104 of the mask substrate 4100 separately from the second membrane 4320 by an LPCVD process.

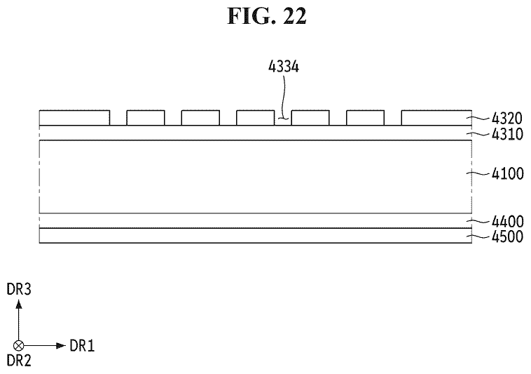

Referring to FIG. 22, the second membrane 4320 may be partially removed to form the second pixel openings 4334 extending through the second membrane 4320. For example, after forming a photoresist pattern that exposes portions where the second pixel openings 4334 are to be formed on the second membrane 4320, an anisotropic etching process, e.g., a reactive ion etching (RIE) process, may be performed utilizing the photoresist pattern as an etching mask to form the second pixel openings 4334 extending through the second membrane 4320.

For example, if (e.g., when) the second membrane 4320 includes silicon nitride (e.g., SiNₓ, wherein 0<x≤2; e.g., Si₃N₄), the RIE process may be performed using a first reactive gas, such as CF₄, C₂F₆, C₄F₆, C₄F₈, CH₃F, CH₂F₂, CHF₃, NF₃, and/or SF₆, containing fluorine, a second reactive gas, such as O₂, NO, and/or NO₂, containing oxygen, and a sputtering gas, such as He, Ne, Ar, and/or Xe, until the first membrane 4310 is exposed. In this case, the first membrane 4310 may be to function as an etch stop film in the RIE process, and the photoresist pattern may be removed by an ashing process and/or a stripping process after the second pixel openings 4334 are formed.

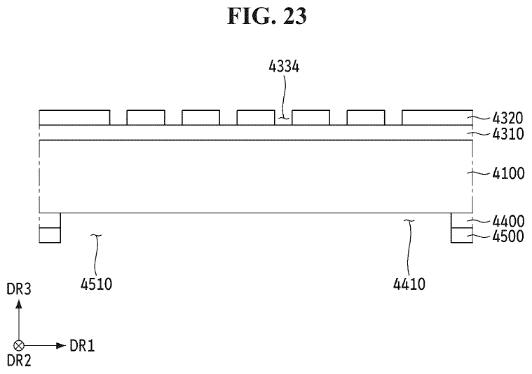

Referring to FIG. 23, the rear inorganic film 4500 and the intermediate inorganic film 4400 may be partially removed to form the rear openings 4510 and the intermediate openings 4410 that expose rear portions of the mask substrate 4100. For example, a photoresist pattern that exposes portions where the rear openings 4510 are to be formed may be formed on the rear inorganic film 4500, and an anisotropic etching process, e.g., an RIE process, may be performed utilizing the photoresist pattern as an etching mask to form the rear openings 4510 and the intermediate openings 4410. The RIE process may be performed until the rear portions of the mask substrate 4100 are exposed, and the photoresist pattern may be removed by an ashing process and/or a stripping process after the rear openings 4510 and the intermediate openings 4410 are formed.

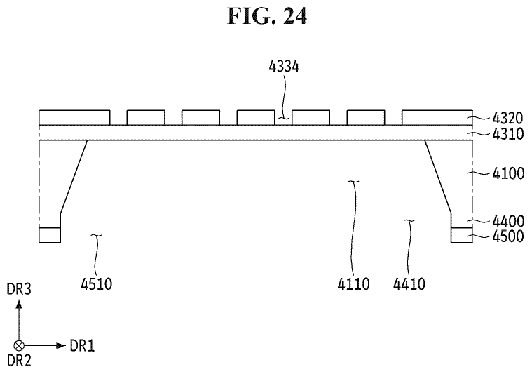

Referring to FIG. 24, the mask substrate 4100 may be partially removed to form the cell openings 4110 that exposes the first membrane 4310. According to one or more embodiments, the cell openings 4110 may be formed through an anisotropic etching process utilizing the rear inorganic film 4500 and the intermediate inorganic film 4400 as an etching mask. For example, the cell openings 4110 may be formed by a wet etching process utilizing an etchant, such as a TMAH solution and/or a KOH solution.

According to one or more embodiments, the <100> crystal direction of the single crystal silicon substrate utilized as the mask substrate 4100 may be the third direction DR3, and accordingly, the cell openings 4110 may have a width that gradually decreases from the rear surface 4104 of the mask substrate 4100 toward the front surface 4102 of the mask substrate 4100 through the wet etching process. For example, inner side surfaces of the cell openings 4110 may have an inclination angle of about 54.7° with respect to the rear surface 4104 of the mask substrate 4100.

According to one or more embodiments, the first membrane 4310 may be to function as an etch stop film during the formation of the cell openings 4110. For example, if (e.g., when) the first membrane 4310 is not provided, the etchant may be provided onto the front surface 4102 of the mask substrate 4100 through the second pixel openings 4334, and hydrogen bubbles may be generated in the second pixel openings 4334 by a reaction between the etchant and the mask substrate 4100. In this case, the second membrane 4320 may be damaged by the hydrogen bubbles. The first membrane 4310 may prevent an etchant from being provided (or reduce a degree to or occurrence of which an etchant is provided) onto the front surface 4102 of the mask substrate 4100 through the second pixel openings 4334, thereby preventing damage (or reducing a degree or occurrence of damage) to the second membrane 4320.

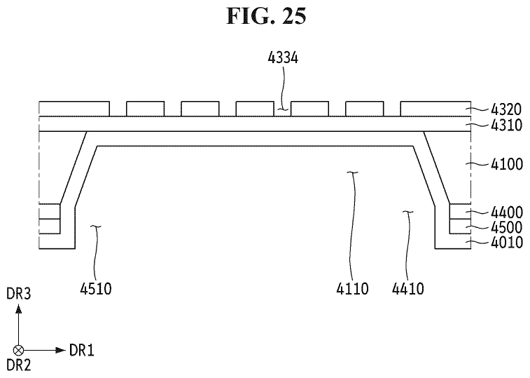

Referring to FIGS. 25 to 27, the first pixel openings 4332 extending through the first membrane 4310 may be formed. According to one or more embodiments, the first pixel openings 4332 may be formed such that the second pixel openings 4334 and the cell openings 4110 communicate with each other, thereby forming the pixel openings 4330 that penetrate the first membrane 4310 and the second membrane 4320.

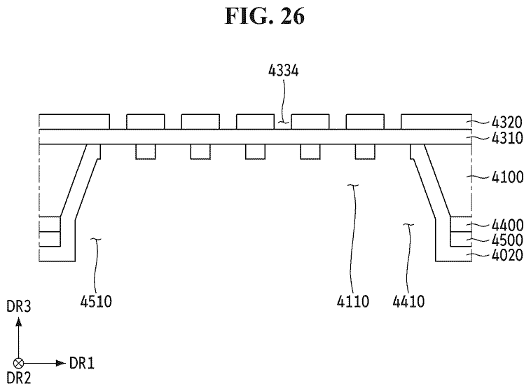

According to one or more embodiments, as illustrated in FIG. 25, a photoresist film 4010 may be formed on the first membrane 4310 exposed through the cell openings 4110. According to one or more embodiments, the photoresist film 4010 may be formed with a substantially uniform thickness on portions of the first membrane 4310 exposed through the cell openings 4110, on the inner side surfaces of the cell openings 4110, and on the rear inorganic film 4500 by a conformal coating process, such as a spray coating process, a dip coating process, and/or a vapor deposition process. Subsequently, an exposure process and a development process may be performed, thereby forming a photoresist pattern 4020 that exposes portions where the first pixel openings 4332 are to be formed, as illustrated in FIG. 26.

According to one or more embodiments, the first pixel openings 4332 may be formed by an etching process utilizing the photoresist pattern 4020 as an etching mask. For example, the first pixel openings 4332 may be formed by an anisotropic etching process, such as a plasma etching process and/or an RIE process. In another example, the first pixel openings 4332 may be formed by an isotropic etching process, such as a wet etching process. The etching process may be performed until the second pixel openings 4334 of the second membrane 4320 are exposed, and the photoresist pattern 4020 may be removed by an ashing process and/or a stripping process after the first pixel openings 4332 are formed.

According to one or more embodiments, the distance d1 (see FIG. 19) between the first pixel openings 4332 may be smaller than the distance d2 (see FIG. 19) between the second pixel openings 4334. For example, the distance d1 between the first pixel openings 4332 may range from about 0.2 times to about 0.8 times the distance d2 between the second pixel openings 4334.

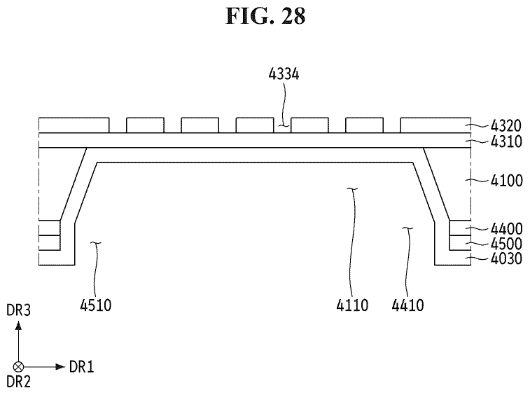

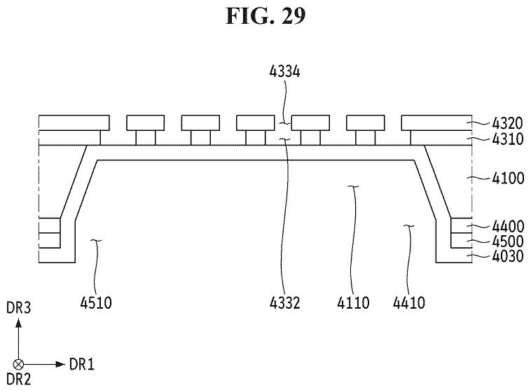

FIGS. 28 and 29 are schematic cross-sectional views illustrating a method of manufacturing a deposition mask according to one or more embodiments of the present disclosure.

Referring to FIG. 28, after forming the cell openings 4110, an etch stop film 4030 may be formed on the first membrane 4310 exposed through the cell openings 4110. For example, the etch stop film 4030 may be a photoresist film or an amorphous (e.g., non-crystalline) silicon film and may be formed with a substantially uniform thickness on portions of the first membrane 4310 exposed through the cell openings 4110, on the inner side surfaces of the cell openings 4110, and on the rear inorganic film 4500. For example, the photoresist film may be formed by a conformal coating process, such as a spray coating process, a dip coating process, and/or a vapor deposition process, and the amorphous (e.g., non-crystalline) silicon film may be formed by a CVD process.

Referring to FIG. 29, the first membrane 4310 may be partially removed to form the first pixel openings 4332. For example, the first pixel openings 4332 may be formed by a wet etching process utilizing the second membrane 4320 as an etching mask. During the wet etching process, an etchant may be provided onto the first membrane 4310 through the second pixel openings 4334. The wet etching process may be performed until the etch stop film 4030 is exposed. For example, if (e.g., when) the first membrane 4310 includes silicon oxide (e.g., SiOₓ, wherein 0<x≤2; e.g., SiO₂), the wet etching process may be performed utilizing an etchant, such as a buffered oxide etchant (BOE) and/or diluted HF. In another example, if (e.g., when) the first membrane 4310 includes silicon nitride (e.g., SiNₓ, wherein 0<x≤2; e.g., Si₃N₄), the wet etching process may be performed utilizing an etchant containing phosphoric acid (H₃PO₄).

Undercut structures may be formed between the first pixel openings 4332 and the second pixel openings 4334 by the wet etching process, and thus the distance d1 (see FIG. 19) between the first pixel openings 4332 may be smaller than the distance d2 (see FIG. 19) between the second pixel openings 4334. For example, the distance d1 between the first pixel openings 4332 may range from about 0.2 times to about 0.8 times the distance d2 between the second pixel openings 4334.

The etch stop film 4030 may be removed after the first pixel openings 4332 are formed. For example, if (e.g., when) a photoresist film is utilized as the etch stop film 4030, the photoresist film may be removed by an ashing process and/or a stripping process. In another example, if (e.g., when) an amorphous (e.g., non-crystalline) silicon film is utilized as the etch stop film 4030, the amorphous silicon film may be removed by a wet etching process utilizing an etchant, such as a TMAH solution and/or a KOH solution.

According to one or more embodiments of the present disclosure, the cell warpage (e.g., a degree or occurrence of the cell warpage) of the deposition mask 4000 may be reduced by the first membrane 4310 and the second membrane 4320 having different residual stresses, and the global warpage (e.g., a degree or occurrence of the global warpage) of the deposition mask 4000 may be reduced by the intermediate inorganic film 4400 and the rear inorganic film 4500. Accordingly, the pixel position accuracy (PPA) and size uniformity of the light emitting layers formed on the backplane substrate 3000 may be significantly or substantially improved or enhanced.

A light-emitting device, a display device, a display apparatus, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

While the subject matter of the present disclosure has been described in connection with certain embodiments, it is to be understood that the subject matter of the present disclosure is not limited to the disclosed embodiments, but, on the contrary, the present disclosure is intended to cover one or more suitable modifications and equivalent arrangements included within the spirit and scope of the appended claims, and equivalents thereof.

What is claimed is:

1. A deposition mask comprising:
a mask substrate having a cell opening; and
a membrane on the mask substrate and having pixel openings to communicate with the cell opening,
wherein the membrane comprises a first membrane on the mask substrate and a second membrane on the first membrane,
the pixel openings comprise first pixel openings extending through the first membrane and second pixel openings extending through the second membrane, and
a distance between the first pixel openings is smaller than a distance between the second pixel openings.

2. The deposition mask as claimed in claim 1, wherein the distance between the first pixel openings is from 0.2 times to 0.8 times the distance between the second pixel openings.

3. The deposition mask as claimed in claim 1, wherein one selected from among the first membrane and the second membrane has residual tensile stress, and
another one selected from among the first membrane and the second membrane has residual compressive stress.

4. The deposition mask as claimed in claim 1, wherein the first membrane comprises silicon oxide or metal having residual compressive stress, and
the second membrane comprises silicon nitride having residual tensile stress.

5. The deposition mask as claimed in claim 4, wherein the membrane is on a front surface of the mask substrate, and
when the first membrane comprises the silicon oxide, an intermediate inorganic film having residual compressive stress is on a rear surface of the mask substrate, and a rear inorganic film having residual tensile stress is on the intermediate inorganic film.

6. The deposition mask as claimed in claim 4, wherein the membrane is on a front surface of the mask substrate, and
when the first membrane comprises the metal, a rear inorganic film having residual tensile stress is on a rear surface of the mask substrate.

7. The deposition mask as claimed in claim 6, wherein the rear inorganic film comprises silicon nitride and has a thickness less than a thickness of the second membrane.

8. The deposition mask as claimed in claim 1, wherein the first membrane comprises silicon nitride having residual tensile stress, and
the second membrane comprises metal having residual compressive stress.

9. The deposition mask as claimed in claim 8, wherein the membrane is on a front surface of the mask substrate, and
a rear inorganic film having residual compressive stress is on a rear surface of the mask substrate.

10. The deposition mask as claimed in claim 1, wherein the first membrane is a composite film in which a plurality of silicon oxide films and at least one silicon nitride film are alternately stacked, and
the second membrane comprises silicon nitride having residual tensile stress.

11. A method comprising:
forming a first membrane on a mask substrate;
forming a second membrane on the first membrane;
forming second pixel openings extending through the second membrane;
forming a cell opening exposing the first membrane through the mask substrate; and
forming first pixel openings connecting the second pixel openings and the cell opening through the first membrane,
wherein a distance between the first pixel openings is smaller than a distance between the second pixel openings, and
wherein the method is a method of manufacturing a deposition mask.

12. The method as claimed in claim 11, wherein the first membrane comprises silicon oxide or metal having residual compressive stress, and
the second membrane comprises silicon nitride having residual tensile stress.

13. The method as claimed in claim 11, wherein the first membrane comprises silicon nitride having residual tensile stress, and
the second membrane comprises metal having residual compressive stress.

14. The method as claimed in claim 11, wherein the first membrane is a composite film in which a plurality of silicon oxide films and at least one silicon nitride film are alternately stacked, and
the second membrane comprises silicon nitride having residual tensile stress.

15. The method as claimed in claim 11, wherein the forming of the first pixel openings comprises:
forming a photoresist pattern that exposes portions where the first pixel openings are to be formed on the first membrane exposed through the cell opening; and
performing an etching process utilizing the photoresist pattern as an etching mask to form the first pixel openings.

16. The method as claimed in claim 15, wherein the forming of the photoresist pattern comprises:
forming a photoresist film on the first membrane exposed through the cell opening by performing a conformal coating process; and
forming the photoresist pattern by performing an exposure process and a development process.

17. The method as claimed in claim 11, wherein the forming of the first pixel openings comprises:
forming an etch stop film on the first membrane exposed through the cell opening; and
performing an etching process utilizing the second membrane as an etching mask to form the first pixel openings.

18. The method as claimed in claim 17, wherein the etch stop film is a photoresist film formed by a conformal coating process or an amorphous silicon film formed by a chemical vapor deposition process.

19. An electronic device comprising a display panel, wherein:
the display panel comprises a backplane substrate and a plurality of light emitting layers formed on the backplane substrate by utilizing a deposition mask,
the deposition mask comprises a mask substrate having a cell opening, and a membrane on the mask substrate and having pixel openings to communicate with the cell opening,
the membrane comprises a first membrane on the mask substrate and a second membrane on the first membrane,
the pixel openings comprise first pixel openings extending through the first membrane and second pixel openings extending through the second membrane,
a distance between the first pixel openings is smaller than a distance between the second pixel openings, and
the plurality of light emitting layers are formed by a deposition process that provides a vapor deposition material through the cell opening and the pixel openings.

20. The electronic device as claimed in claim 19, further comprising at least one selected from among a processor, a memory, and a power module.
